(19) United States
(12) Patent Application Publication
(10) Pub. No.: US 2020/0103456 A1
(43) Pub. Date: Apr. 2, 2020

(54) MEASUREMENT METHOD, DIAGNOSTIC DEVICE FOR DIAGNOSING TRANSMISSION LINE, DETECTION DEVICE, AND LINEAR SENSOR DEVICE

(71) Applicant: YAZAKI CORPORATION, Tokyo (JP)

(72) Inventors: Hajime Terayama, Susono-shi (JP); Yuji Hakii, Susono-shi (JP); Takahiro Kato, Susono-shi (JP); Naoyuki Shiraishi, Susono-shi (JP); Kosuke Unno, Susono-shi (JP); Shingo Tanaka, Susono-shi (JP)

(21) Appl. No.: 16/583,225

(22) Filed: Sep. 25, 2019

(30) Foreign Application Priority Data
Sep. 28, 2018 (JP) 2018-185322
Aug. 23, 2019 (JP) 2019-153077

(51) Int. Cl. G01R 31/08; G01R 29/08; G01F 23/26; G01D 5/20; G01P 15/125; G01L 9/12

(52) U.S. Cl. CPC G01R 31/085; G01R 29/0892; G01L 9/12; G01D 5/20; G01P 15/125; G01F 23/26

(57) ABSTRACT

In a method to measure changes of the pair of differential transmission lines, an in-phase signal is generated by combining first and second signals transmitted through the pair of differential transmission lines, a phase of the second signal being opposite to the first signal. In a transmission line diagnostic device, a signal combiner extracts the first and second signals received by a communication unit, combines the extracted those signals, and generates an in-phase signal, a detector detects the generated in-phase signal, and a determination unit determines an error when a magnitude of the detected in-phase signal is equal to or greater than a threshold value. In a liquid level detection device, a combining unit combines the first and second signals and generate an in-phase signal, a detection unit detects a voltage of the generated in-phase signal, and a calculation unit calculates a liquid level from the detected voltage.

### CROSS-REFERENCE TO RELATED APPLICATIONS

This application is based on and claims priority under 35 USC 119 from Japanese Patent Application No. 2018-185322 filed on Sep. 28, 2018 and Japanese Patent Application No. 2019-153077 filed on Aug. 23, 2019, the contents of which are incorporated herein by reference.

### TECHNICAL FIELD

The present disclosure relates to a measurement method, diagnostic device for diagnosing a transmission line, a detection device, and a linear sensor device.

### BACKGROUND ART

The measurement of a transmission line in a differential transmission line that transmits signals whose phases are opposite to each other to a pair of signal lines is performed by measuring a combined signal (a differential signal) obtained by combining one signal which is used as it is and the other signal which is inverted. FIG. 23 illustrates a configuration of a measurement system 100 that detects the differential signal. Signals whose phases are opposite to each other are transmitted to a pair of signal lines (differential transmission cables) 110 of connecting communication devices A and B. Out of the signals extracted by the communication device A, one signal which is used as it is and the other signal which is inverted are combined by a combiner 101. The combined signal (the differential signal) is inputted to a measurement device C and measured thereby. FIG. 24 is a diagram illustrating a waveform example of the differential signal. An input signal I1 inputted to a driver D is transmitted through a differential transmission cable 110 in the form of a positive signal and a negative signal, is combined by a receiver R, and is outputted as an output signal OD1. In a normal state, as illustrated in FIG. 24A, the output signal OD1 has the same waveform as that of the input signal I1. On the other hand, when an abnormality occurs in the transmission line, the output signal OD2 has a different waveform from that of the input signal I1 as illustrated in FIG. 24B.

When measuring a change in the transmission line by measuring the differential signal, it is difficult to detect a change in the combined signal because the change in the combined signal becomes an extremely small amount with respect to the change in the transmission line. Therefore, for example, as illustrated in JP 2017-092621 A, a device which combines various methods is proposed.

JP 2013-185864 A, JP 2003-244034 A, and JP 2010-276586 A disclose a technology related to cable diagnosis; JP 2015-004561 A, JP 2007-240472 A, JP 2013-108958 A, and JP 2012-225788 A disclose a technology related to a liquid level sensor; and JP 2016-001123 A, JP 2001-201363 A, and JP 2011-137748 A disclose a technology related to a displacement sensor. Further, JP 2011-137746 A, JP 2017-133841 A, JP 2013-104797 A, and JP 2014-182031 A disclose a technology related to a pressure sensor; JP 2017-067500 A, JP 2013-160559 A, and JP 2011-185828 A disclose a technology related to an acceleration sensor; and “Imai Michio et al. “Structural Monitoring by Optical Fiber Sensor” 2019 IEICE (The Institute of Electronics, Information and Communication Engineers) General Conference, BI-8-1, pp. SS-79-80, Mar. 19-22, 2019” and “Minaguchi Shu et al, “Life Cycle Monitoring of Aerospace Composite Structures” 2019 IEICE (The Institute of Electronics, Information and Communication Engineers) General Conference, BI-8-2, pp. SS-81, Mar. 19-22, 2019” disclose a technology related to an optical fiber sensor.

According to the technology disclosed in JP 2017-092621 A, a measurement system for detecting a change in a transmission line is complicated.

### SUMMARY OF INVENTION

The present disclosure is to provide a measurement method and a transmission line diagnostic device capable of easily detecting a change in a transmission line with a simple configuration. And, the present disclosure is to provide a compact and highly accurate detection device for a liquid level, and the like.

According to an aspect of the present disclosure, a measurement method includes generating an in-phase signal by combining a first signal transmitted through a first transmission line and a second signal transmitted through a second transmission line in a pair of differential transmission lines including the first transmission line through which the first signal is transmitted and the second transmission line through which the second signal whose phase is opposite to the first signal is transmitted, and measuring the generated in-phase signal.

According to the aspect of the present disclosure, the measurement method further includes amplifying the generated in-phase signal, and measuring the amplified in-phase signal.

According to the aspect of the present disclosure, the measurement method further includes measuring the generated in-phase signal after a signal of a frequency band higher than a target frequency band is attenuated.

According to the aspect of the present disclosure, the measurement method further includes extracting the first signal transmitted through the first transmission line and the second signal transmitted through the second transmission line by a directional coupler.

According to another aspect of the present disclosure, a diagnostic device for diagnosing a transmission line includes a mounting unit on which a pair of differential transmission lines including a first transmission line through which a first signal is transmitted and a second transmission line through which a second signal whose phase is opposite to the first signal is transmitted is mounted, a first communication unit configured to transmit the first signal and the second signal to the differential transmission line via the mounting unit, a second communication unit configured to receive the first signal and the second signal from the differential transmission line via the mounting unit, a signal combiner configured to extract the first signal and the second signal received by the second communication unit, combine the extracted first and second signals, and generate an in-phase signal, a detector configured to detect the generated in-phase signal.

According to the aspect of the present disclosure, the diagnostic device further includes a determination unit configured to determine an error when a magnitude of the detected in-phase signal is equal to or greater than a threshold value.

According to the aspect of the present disclosure, the diagnostic device further includes an amplifier configured to amplify the in-phase signal generated by the signal combiner. The detector detects the in-phase signal amplified by the amplifier.

According to the aspect of the present disclosure, the determination unit determines whether the error exists by extracting the first signal and the second signal received by the second communication unit and comparing the extracted first and second signals with data of a normal characteristic stored in a memory.

According to another aspect of the present disclosure, a detection device includes a first line to which a first signal is inputted, a second line to which a second signal whose phase is opposite to the first signal is inputted, a combining unit configured to combine the first signal transmitted through the first line and the second signal transmitted through the second line and generate an in-phase signal, a detection unit configured to detect a voltage of the generated in-phase signal, and a calculation unit configured to calculate a liquid level from the detected voltage.

According to the aspect of the present disclosure, the detection device further includes an amplification unit configured to amplify the generated in-phase signal. The detection unit detects a voltage of the amplified in-phase signal.

According to the aspect of the present disclosure, the calculation unit calculates the liquid level with reference to a table indicating the correspondence between the liquid level and the voltage.

According to the aspect of the present disclosure, the first line includes a first open stub. The second line includes a second open stub. The combining unit generates the in-phase signal by combining the first signal passing through the first open stub and the second signal passing through the second open stub.

According to another aspect of the present disclosure, a detection device includes a first sensor to which a first signal is inputted, a second sensor to which a second signal whose phase is opposite to the first signal is inputted, a combining unit configured to generate an in-phase signal by combining the first signal passing through the first sensor and the second signal passing through the second sensor, a detection unit configured to detect a voltage of the generated in-phase signal, and a calculation unit configured to calculate a displacement level or a pressure from the detected voltage.

According to the aspect of the present disclosure, at least one of the first sensor and the second sensor includes a loop coil. The calculation unit is configured to calculate a distance between the loop coil and a measured object, the distance corresponding to the displacement level.

According to the aspect of the present disclosure, each of the first sensor and the second sensor includes a pair of electrode plates which is disposed to be spaced apart from each other. The calculation unit is configured to calculate a distance between the pair of electrode plates to be changed by pressurization, the distance corresponding to the pressure.

According to another aspect of the present disclosure, a detection device includes a movable electrode, a first fixed electrode and a second fixed electrode that are disposed to be spaced apart from the movable electrode and are opposite to each other across the movable electrode, a detection unit configured to detect a voltage of an in-phase signal obtained by combining a first signal passing through between the movable electrode and the first fixed electrode, and a second signal passing through between the movable electrode and the second fixed electrode, and a calculation unit configured to calculate an acceleration from the detected voltage.

According to another aspect of the present disclosure, a linear sensor device includes at least two communication devices, a first transmission line and a second transmission line that are disposed between the at least two communication devices, the first transmission line and the second transmission line having a line length substantially same as each other, a combiner configured to generate an in-phase signal by combining a first signal passing through the first transmission line and a second signal passing through the second transmission line, and a measurement device that is configured to measure the generated in-phase signal.

According to the measurement method, since the in-phase signal obtained by combining the first signal and the second signal without inverting the first signal and the second signal can capture a shift in an amplitude and a phase between the pair of transmission lines more than a differential signal obtained by combining the first signal and the inverted second signal, a change in the transmission line can be easily detected, and the measurement system can be simplified.

According to the measurement method, a minute change in the transmission line can be easily detected by amplifying the in-phase signal.

According to the measurement method, since noise overlapped on an unnecessary band can be removed, a stable detection output can be obtained with higher sensitivity.

According to the measurement method, when an original signal flowing through the differential transmission line is separated and extracted, the loss of the original signal can be minimized. Since it is possible to distinguish where an abnormality occurs in the front and rear places centering on an arrangement place (a signal separation position) of a directional coupler, a function as a sensor of a differential transmission system can be improved.

According to the diagnostic device for diagnosing the transmission line, since the in-phase signal obtained by combining the first signal and the second signal without inverting the first signal and the second signal can capture the shift in the amplitude and the phase between the pair of transmission lines more than the differential signal obtained by combining the first signal and the inverted second signal, the change in the transmission line can be easily detected such that a minute error can be detected. Since the transmission line diagnostic device is not limited to a method of using a diagnostic signal as the first signal and the second signal and can perform diagnosis using an actual communication signal, the transmission line diagnostic device is highly versatile. When performing the diagnosis using the communication signal, since a communication system using a differential transmission line (a cable, and the like) which is an object to be diagnosed can be used as it is, it is not required to separately construct a diagnostic system for inputting and outputting the diagnostic signal, thereby making it possible to simplify the diagnostic system.

According to the diagnostic device, a minute change in the transmission line can be easily detected by amplifying the in-phase signal.

According to the diagnostic device, even if an error of the same degree is generated in the first transmission line and the second transmission line and a phase difference is not generated between the first signal and the second signal, when a difference exists between data of the first and second signals and data of a normal characteristic, the error of the same degree can be detected as an error, whereby it is possible to perform highly accurate diagnosis.

According to the detection device, a difference corresponding to the liquid level appears as a level of the in-phase signal by installing the first line in a tank which is a measured object for liquid level detection and by using the second line as a reference for correction. That is, since a phase change can be detected instead of an amplitude change of the first signal and the second signal, the liquid level can be detected with high accuracy. Since a sensor is not a capacitance detection type sensor in a related art, a straight-line pattern is sufficient, and since a comb-teeth type pattern for providing capacitance to a substrate of a sensor unit is not required, a sensor shape can be slimmed.

According to the detection device, a minute change in the liquid level can be easily detected by amplifying the in-phase signal.

According to the detection device, the liquid level can be easily calculated with reference to the table prepared in advance.

According to the detection device, the liquid level can be detected only by the open stub and thus the element can be slimmed.

According to the detection device, the displacement, pressure and acceleration can be detected with high accuracy by using the in-phase signal combined without inverting the first signal and the second signal.

According to the linear sensor device, the linear sensor that compensates for a drawback of the optical fiber sensor (conversion loss is large and energy efficiency is low) can be realized.

According to the present disclosure, it is possible to provide a measurement method and a transmission line diagnostic device capable of easily detecting a change in a transmission line with a simple configuration. A compact and highly accurate detection device can be provided.

Hereinabove, the present disclosure is briefly described. The details of the present disclosure will be further clarified by reading through a form (hereinafter, referred to as an “embodiment”) for implementing the invention which will be described hereinbelow with reference to the accompanying drawings.

### BRIEF DESCRIPTION OF DRAWINGS

FIG. 1 is a diagram illustrating a configuration of a measurement system that detects an in-phase signal according to a first embodiment;

FIG. 2 is a diagram illustrating a difference between a differential signal and a combined signal with respect to a phase shift;

FIGS. 3A and 3B are diagrams illustrating examples of waveforms of the in-phase signal;

FIG. 4 is a diagram illustrating a configuration of a measurement system that detects an in-phase signal according to a second embodiment;

FIG. 5 is a diagram illustrating a difference in an in-phase signal level depending on the presence or absence of amplification;

FIG. 6 is a diagram illustrating a configuration of a measurement system that detects an in-phase signal according to a third embodiment;

FIGS. 7A and 7B are diagrams illustrating examples of a common waveform before and after removing an unnecessary band;

FIG. 8 is a conceptual diagram of signal extraction by high impedance according to a fourth embodiment;

FIG. 9 is a conceptual diagram of signal extraction by a directional coupler according to the fourth embodiment;

FIGS. 10A to 10D are conceptual diagrams of signal extraction by a distributing and combining device according to the fourth embodiment;

FIG. 11 is a diagram illustrating a configuration of a cable diagnostic device according to a fifth embodiment;

FIG. 12 is a diagram illustrating a modification of the fifth embodiment;

FIG. 13 is a diagram illustrating a modification of the fifth embodiment;

FIG. 14 is a diagram illustrating a cable diagnostic device according to a sixth embodiment;

FIG. 15 is a diagram illustrating a flow of cable failure diagnosis in the cable diagnostic device according to the sixth embodiment;

FIG. 16 is a diagram illustrating a modification of the sixth embodiment;

FIG. 17 is a diagram illustrating a modification of the sixth embodiment;

FIG. 18 is a diagram illustrating a configuration of a liquid level detection device according to a seventh embodiment;

FIGS. 19A and 19B are diagrams illustrating a simulation model of a sensor unit in the liquid level detection device according to the seventh embodiment;

FIG. 20 is a diagram illustrating a simulation result using the model illustrated in FIGS. 19A and 19B;

FIGS. 21A and 21B are diagrams illustrating a modification of the seventh embodiment;

FIGS. 22A and 22B are diagrams illustrating a modification of the seventh embodiment;

FIG. 23 is a diagram illustrating a configuration of a measurement system that detects a differential signal;

FIGS. 24A and 24B are diagrams illustrating waveform examples of the differential signal;

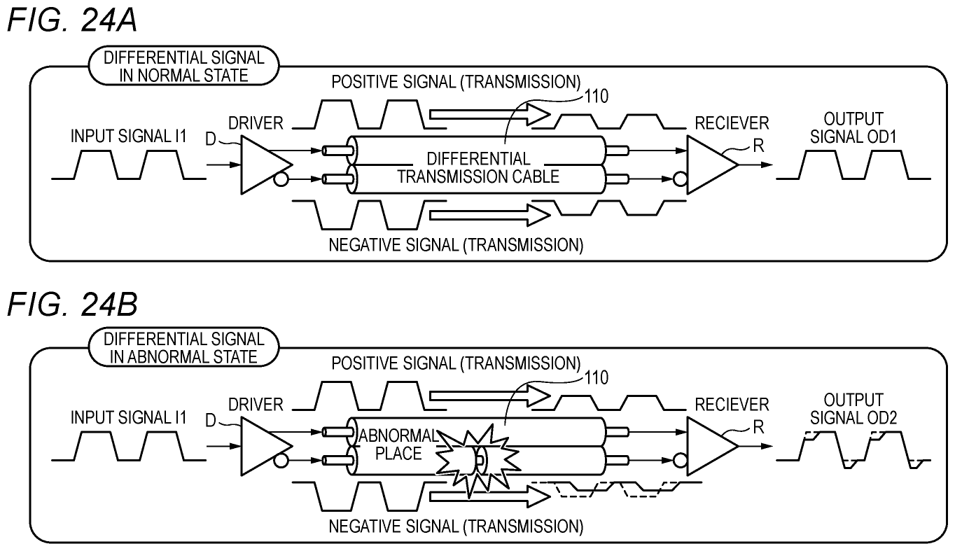

FIGS. 25A and 25B are diagrams illustrating a simulation model of a sensor unit in a liquid level detection device according to an eighth embodiment;

FIGS. 26A and 26B are diagrams illustrating the measurement principle of the liquid level detection device according to the eighth embodiment;

FIG. 27 is a diagram illustrating a frequency characteristic result with respect to a change in a liquid level by a simulation using the model illustrated in FIGS. 25A and 25B;

FIG. 28 is a diagram illustrating a simulation result using the model illustrated in FIGS. 25A and 25B;

FIGS. 29A and 29B are diagrams illustrating a modification of the eighth embodiment;

FIGS. 30A and 30B are diagrams illustrating a modification of the eighth embodiment;

FIG. 31 is a diagram illustrating a configuration of a displacement detection device according to a ninth embodiment;

FIGS. 32A and 32B is a diagram illustrating a simulation model of a sensor unit in the displacement detection device according to the ninth embodiment;

FIG. 33 is a diagram illustrating the measurement principle of the displacement detection device according to the ninth embodiment;

FIG. 34 is a diagram illustrating a change in frequency characteristics according to a change in distance of a metallic block illustrated in FIG. 33;

FIG. 35 is a diagram illustrating a simulation result using the model illustrated in FIGS. 32A and 32B;

FIGS. 36A and 36B are diagrams illustrating a modification of the ninth embodiment;

FIG. 37 is a diagram illustrating a configuration of a pressure detection device according to a tenth embodiment;

FIGS. 38A to 38C are diagrams illustrating a simulation model of a sensor unit in the pressure detection device according to the tenth embodiment;

FIG. 39 is a diagram illustrating a change in frequency characteristics according to a change in a space between electrode plates (a change in pressure) illustrated in FIGS. 38A to 38C;

FIG. 40 is a diagram illustrating a simulation model of the sensor unit in the pressure detection device according to the tenth embodiment;

FIG. 41 is a diagram illustrating a simulation result using the models illustrated in FIGS. 38A to 38C and FIG. 40;

FIG. 42 is a diagram illustrating a modification of the tenth embodiment;

FIG. 43 is a diagram illustrating a modification of the tenth embodiment;

FIG. 44 is a diagram illustrating a configuration of an acceleration detection device according to an eleventh embodiment;

FIGS. 45A and 45B are diagrams illustrating a configuration of a sensor unit in the acceleration detection device according to the eleventh embodiment;

FIG. 46 is a diagram illustrating a simulation model of the sensor unit illustrated in FIGS. 45A and 45B;

FIG. 47 is a diagram illustrating a simulation result (a change in frequency characteristics) using the model illustrated in FIG. 46;

FIG. 48 is a diagram illustrating a simulation result (a change in an output voltage) using the model illustrated in FIG. 46;

FIG. 49 is a diagram illustrating a modification of the eleventh tenth embodiment;

FIG. 50 is a diagram illustrating a modification of the eleventh tenth embodiment;

FIG. 51 is an image diagram of an optical fiber sensor; and

FIGS. 52A to 52C are diagrams illustrating examples of the arrangement of a linear sensor according to a twelfth embodiment.

### DESCRIPTION OF EMBODIMENTS

A specific embodiment of the present invention will be hereinafter described with reference to each drawing.

### First Embodiment: Measurement Method

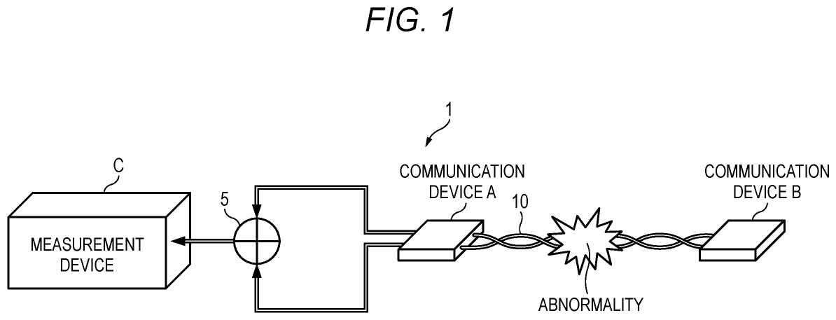

FIG. 1 is a diagram illustrating a configuration of a measurement system 1 that detects an in-phase signal according to a first embodiment. The measurement system 1 includes a communication device A, a communication device B, a pair of differential transmission lines 10 including two transmission lines, a combiner 5, and a measurement device C. The communication device A and the communication device B transmit and receive a positive signal (a first signal) and a negative signal (a second signal) whose polarities are opposite to each other via the differential transmission line 10. The combiner 5 generates an in-phase signal by combining both the positive signal and the negative signal exchanged between the communication device A and the communication device B in the non-inverted form. The measurement device C measures the in-phase signal outputted from the combiner 5. When a change such as a change in a physical shape and a change in a material occurs in a line for transmitting the positive signal of the differential transmission line 10 or a line for transmitting the negative signal thereof, a transmission characteristic with respect to the transmission signal changes at a place (an abnormal place) where the change occurs. The positive signal and the negative signal passing through the abnormal place of the line also generate a difference in an amplitude and a phase. When the amplitude difference and the phase difference occur between the positive signal and the negative signal which are transmitted through the two transmission lines between the communication device A and the communication device B, a slight change generated in the transmission line can be captured by measuring the in-phase signal with the measurement device C.

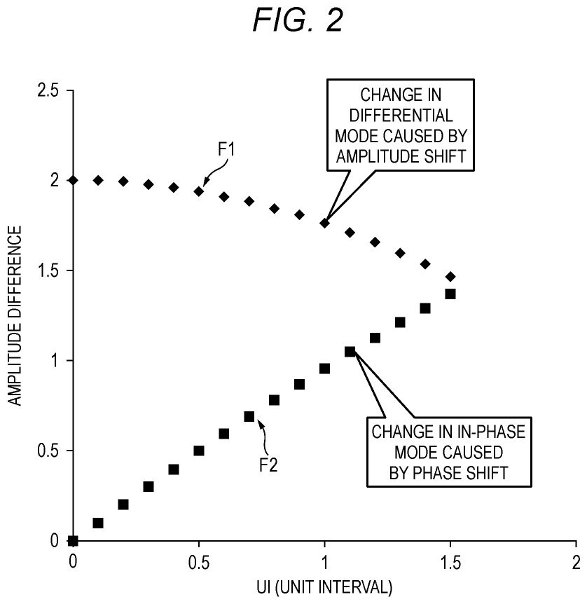

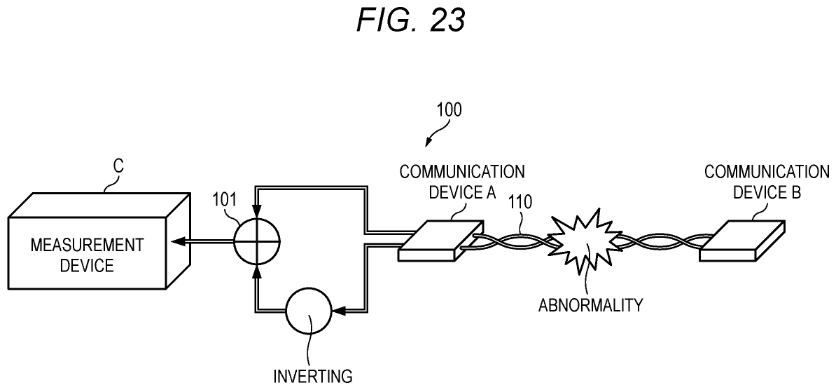

FIG. 2 is a diagram illustrating a difference between a differential signal and a combined signal with respect to a phase shift. A function F1 indicates a change in the differential signal caused by an amplitude shift, and corresponds to a measurement result of a differential signal outputted from a combiner 101 illustrated in FIG. 23. The differential signal is a signal obtained by inverting one of the positive signal and the negative signal transmitted from the differential transmission cable 110 and by combining the positive and negative signals, one of which is inverted. A function F2 indicates a change in the in-phase signal caused by the phase shift, and corresponds to a measurement result of the in-phase signal outputted from the combiner 5 in FIG. 1. According to FIG. 2, since a gradient (a change in the amplitude) of the function F2 is larger than that of the function F1, it can be seen that the in-phase signal is more appropriate for capturing a slight change in comparison with the differential signal.

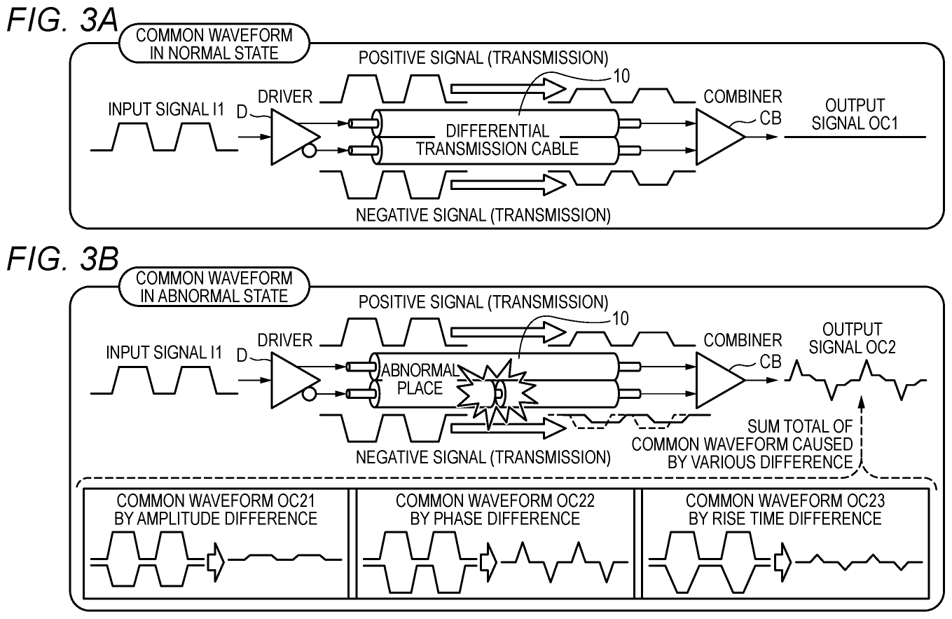

FIGS. 3A and 3B are diagrams illustrating a waveform example of the in-phase signal. FIG. 3A illustrates an example of a waveform (a common waveform) of the in-phase signal in a normal state, that is, when an abnormality does not occur in the differential transmission line 10. An input signal I1 inputted to a driver D is transmitted through the differential transmission line 10 in the form of the positive signal and the negative signal and thereafter, the positive and negative signals are added up by a combiner CB and outputted as an output signal OC1 (the in-phase signal). In the normal state, since no difference exists between the positive signal and the negative signal except the opposite polarity therebetween, when both the positive and negative signals are added up together, both the positive and negative signals mutually cancel each other, whereby nothing remains. FIG. 3B illustrates a waveform example of the in-phase signal when the abnormality occurs in a line for transmitting the negative signal of the differential transmission line 10. The input signal I1 inputted to the driver D is transmitted through the differential transmission line 10 in the form of the positive signal and the negative signal and thereafter, the positive and negative signals are added up by the combiner CB and outputted as an output signal OC2 (in-phase signal). In a case where a difference exists between the positive signal and the negative signal, when both the positive and negative signals are added up together, an in-phase component (a common signal) which cannot be canceled remains. The output signal OC2 is obtained by adding up a common waveform OC21 generated by an amplitude difference, a common waveform OC22 generated by a phase difference, and a common waveform OC23 generated by a rise time difference.

An amount of the common signal (a height of the amplitude, a time length, and the like) depends on (proportional to) a difference between the positive signal and the negative signal. That is, since a common signal change amount and a transmission line change amount have a proportional relationship, a change in the transmission line can be detected by observing an increase from the normal state of the common signal. For example, a degree of the change can be observed by assigning the common signal amount in the normal state to a unit space of the Mahalanobis-Taguchi System and by distinguishing the change (the increase) of the common signal amount as a signal space. A deterioration progress degree in the future can be predicted by observing the transition of the change thereof. As described hereinafter, it is possible to improve the reliability of a communication network system, and a service and a function using the communication network system by predicting a deterioration signal degree. When an abnormality or a failure occurs in a device connected to the communication network or a transmission line forming the communication network, the high-level service and the function formed by using the communication network are lost. Meanwhile, the measurement system 1 according to the embodiment diagnoses and extracts a little sign of the device and the transmission line related to the communication network, and predicts how long the little sign will last and what kind of problem will be generated due to the little sign in the future. Therefore, a countermeasure can be taken against the problem in advance by predicting the deterioration progress degree in the above-described manner, and as a result, it is possible to improve the reliability of the communication network system, and the service and the function using the same.

As described above, according to the measurement system 1 of the embodiment, the slight change generated in the transmission line can be easily detected with high accuracy without causing the measurement system to be complicated by using the in-phase signal for the measurement signal. The reliability of the communication network system and the like can be improved by predicting the deterioration progress degree of the transmission line by using the measurement system 1 according to the embodiment.

### Second Embodiment: Measurement Method

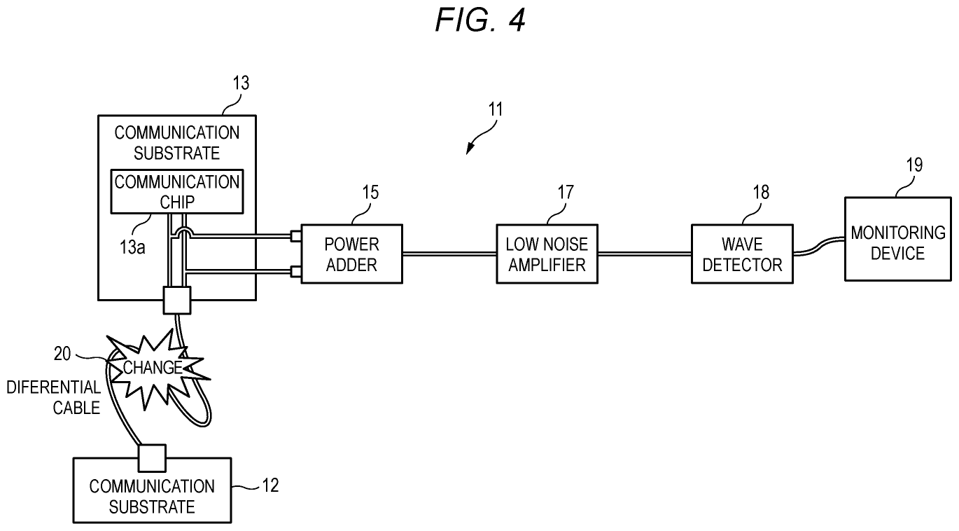

FIG. 4 is a diagram illustrating a configuration of a measurement system 11 that detects an in-phase signal in a second embodiment. The measurement system 11 includes a communication substrate 12, a communication substrate 13 including a communication chip 13a, a power adder 15, a low noise amplifier 17, a wave detector 18, a monitoring device 19, and a pair of differential cables 20 including two transmission lines. The differential cable 20 is connected between the communication substrate 12 and the communication substrate 13. The communication substrate 12 and the communication substrate 13 transmit and receive a positive signal and a negative signal whose polarities are opposite to each other via the differential cable 20. The power adder 15 generates the in-phase signal by combining both the positive signal and the negative signal exchanged between the communication substrate 12 and the communication chip 13a as they are (non-inversion). The low noise amplifier 17 amplifies the in-phase signal generated by the power adder 15. The wave detector 18 converts an amplitude level of the in-phase signal which is a high frequency signal into an analog value, and then outputs the converted analog value as a detection voltage. The monitoring device 19 observes the detection voltage (a detection output) outputted from the wave detector 18. When an abnormality occurs in the differential cable 20 and an amplitude difference and a phase difference appear between the positive signal and the negative signal transmitted by the differential cable 20, a slight change generated in the transmission line can be captured by observing the detection output from the wave detector 18 with the monitoring device 19. Since the in-phase signal is amplified by the low noise amplifier 17, the slight change generated in the transmission line can be captured with high sensitivity. The change can be easily confirmed by a general wide band wave detector in such a manner that the in-phase signal is amplified, for example, by about 30 dB by the low noise amplifier 17.

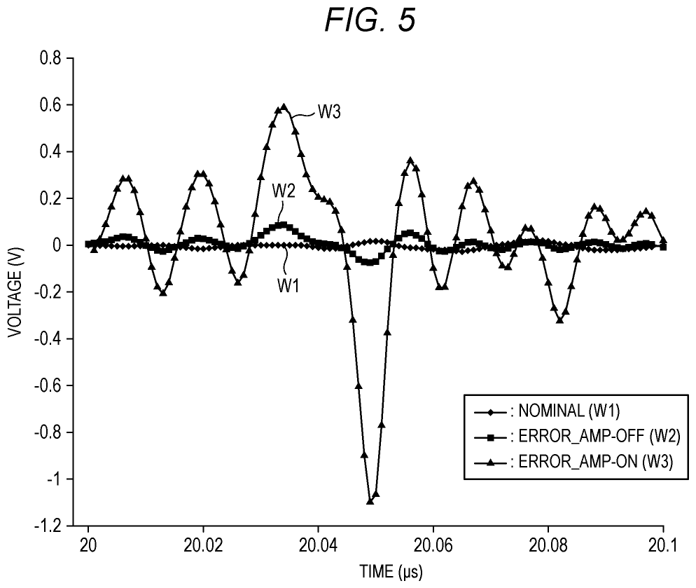

FIG. 5 is a diagram illustrating a difference in an in-phase signal level depending on the presence or absence of amplification. A graph illustrated in FIG. 5 indicates a waveform (a common waveform) W1 of the in-phase signal in an initial state of the differential cable 20; a common waveform W2 of a component (non-amplified) when an abnormality occurs in the differential cable 20 (an abnormal state); and an amplified common waveform W3 when an abnormality occurs in the differential cable 20 (an abnormal state). When the amplification is not performed, a difference between the maximum values of the common waveforms W1 and W2 respectively in the initial state and the abnormal state is about several tens of mV. On the other hand, when the amplification is performed, the difference between the maximum values of the common waveforms W1 and W3 respectively in the initial state and the abnormal state is emphasized up to several hundreds of mV. Accordingly, it can be easily seen from FIG. 5 that the capability of sensing the change in the transmission line is increased.

In the embodiment, an amplified signal is converted into a voltage through effective value detection by the wave detector 18. The detection voltage is assumed as a sensor output. In the embodiment, the wave detector 18 performs the effective value detection, but another detection method may be applied thereto. An example of the detection method includes a method using an average value and a peak value, a diode envelope, and a method of obtaining an effective value by calculation using an IC in addition to logarithm (Log) detection and straight line (linear) detection. The Log detection is suitable for detection of a weak signal and a voltage output corresponding to a high frequency signal level (dBm) can be obtained. The Log detection has a wide corresponding range, but has low resolution (accuracy). On the other hand, even though the linear detection is not suitable for detecting the weak signal, a proportional relationship can be obtained between an input and an output. In the linear detection, a corresponding range is narrow, but the resolution (the accuracy) is high. The amplification of the in-phase signal in the embodiment is also effective for any detection method.

As described above, the measurement system 11 according to the embodiment can improve the sensitivity as a sensor by amplifying the in-phase signal in addition to the effect of the first embodiment.

### Third Embodiment: Measurement Method

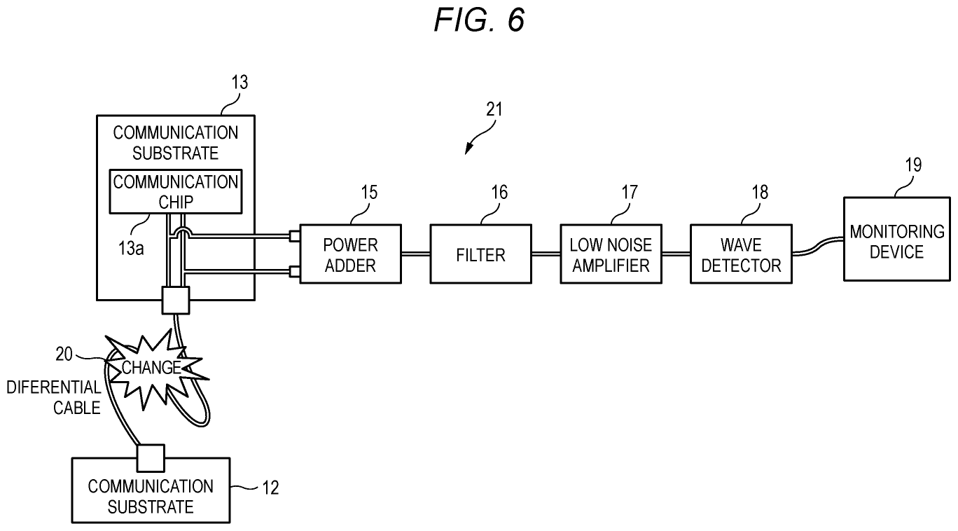

FIG. 6 is a diagram illustrating a configuration of a measurement system 21 that detects an in-phase signal in a third embodiment. The measurement system 21 in FIG. 6 is configured by adding a filter 16 to the measurement system 11 according to the second embodiment illustrated in FIG. 4. Hereinafter, a configuration different from that of the second embodiment will be mainly described. The filter 16 attenuates a signal in a frequency band (an unnecessary band) higher than a target frequency band. The filter 16 is disposed between the power adder 15 and the low noise amplifier 17.

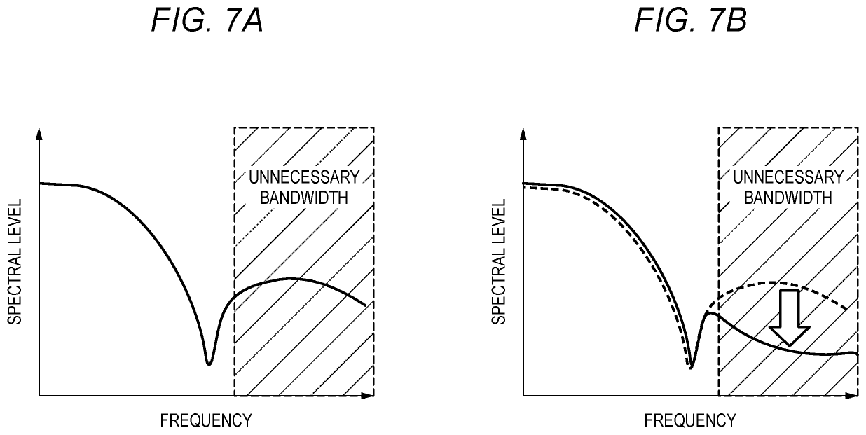

FIGS. 7A and 7B are diagrams illustrating examples of a common waveform before and after removing the unnecessary band. When an in-phase signal of differential digital transmission is used as a measurement signal, a detection level changes due to an influence of noise entering into a wide band included in the wave detector 18 and there is a possibility of misdiagnosing that a change exists even though no change occurs in a cable. Therefore, a band other than a band required for information transmission is cut by the filter 16. FIG. 7A illustrates a common waveform when the filter 16 is not applied. FIG. 7B illustrates a common waveform when, for example, a frequency band of 80 MHz or higher is attenuated by the filter 16. When a valid common waveform appears only at 80 MHz or lower, noise overlapped on the unnecessary band can be removed by attenuating the frequency band of 80 MHz or higher by the filter 16, whereby diagnosis using only the in-phase signal generated by the change of the transmission line can be performed.

Table 1 indicates a difference in detection output voltage values depending on the presence or absence of the filter 16.

TABLE 1

| | Initial | Transmission | Width of |
|---|---|---|---|
| Detection output | transmission | line after | detection |
| voltage value | line | change | output |
| Without filter | 2.5 V | 3.5 V | 1.0 V |
| With filter | 1.8 V | 3.3 V | 1.5 V |

In Table 1, a width of the detection output is a difference between a detection output voltage value in an initial transmission line and a detection output voltage value in the transmission line after the change. In the initial transmission line, a difference between the detection output voltage values with and without the filter 16 can be seen because noise is included therein in addition to the common waveform that does not appear unless the original transmission line changes. In the transmission line after the change, the difference between the detection output voltage values with and without the filter 16 can be seen because of a fact that a frequency band of the noise overlaps a frequency band of the common signal which increases due to the change of the transmission line and a fact that a degree of the change of the common waveform due to the change of the transmission line is larger than the noise. Since the width 1.0V of the detection output without the filter 16 is smaller than the width 1.5V of the detection output with the filter 16, the change in the transmission line is buried in the noise when the noise is not removed, whereby it can be seen that the sensitivity as a sensor deteriorates. Conversely, it is possible to improve the sensitivity of the function of detecting the common waveform and obtaining the sensor output by removing the unnecessary band (a noise band) by the filter 16.

As described above, according to the measurement system 21 of the embodiment, in addition to the effects of the first and second embodiments, it is possible to obtain the stable detection output with higher sensitivity by removing the signal of the frequency band (the unnecessary band) higher than the target frequency band.

### Fourth Embodiment: Measurement Method

In the embodiment, in the measurement systems 1, 11, and 21 described in the first embodiment to the third embodiment, a method of extracting the in-phase signal from the positive signal and the negative signal (an original signal) to be received at a transmission unit will be described. When using the in-phase signal, it is important to extract the in-phase signal at the signal level as large as possible while minimizing an influence on the original signal. A transmission standard is related to an information system transmission line, and it is not permitted to inadvertently attenuate or distort the original signal exchanged between the communication devices. In a method of equivalently distributing and combining the original signal, the signal level of the original signal may be halved, such that the lowest reception level determined by a communication standard may not be obtained. As a signal extraction method of minimizing the lowering of the original signal level due to branching, the inventors devised a method using A) high impedance, B) a directional coupler, and C) a coupler, a divider, and a combiner (a distributing and combining device). Hereinafter, in FIG. 4, an example of extracting a distribution signal (a distribution output) transmitted to the power adder 15 from the original signal (differential signal positive and differential signal negative) transmitted to a main transmission line from the differential cable 20 to the communication chip 13a will be described.

### A) Signal Extraction Method by High Impedance

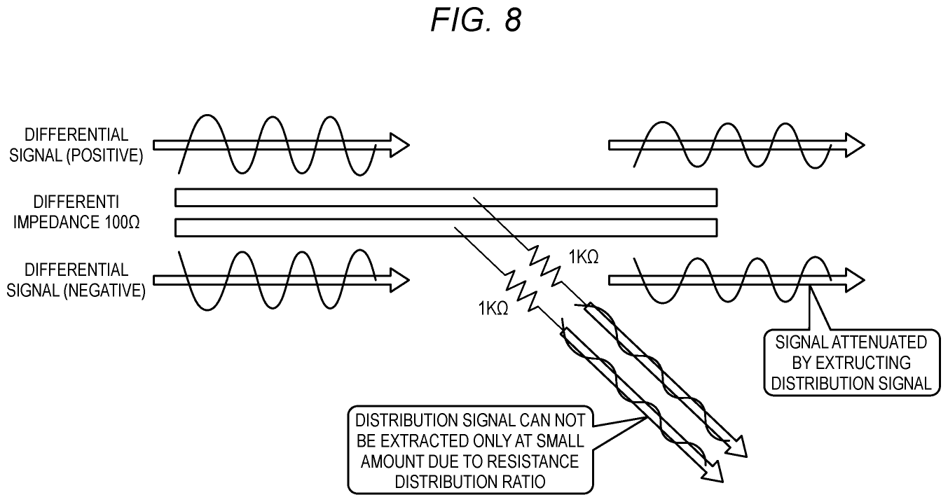

FIG. 8 is a conceptual diagram of signal extraction by high impedance. A method illustrated in FIG. 8 branches a line with a high resistance value (a resistance amount equally regarded as open when viewed from the differential transmission line) and extracts the distribution signal therefrom so as not to affect a signal waveform of the original signal of the transmission line. According to the method described above, the distribution signal can be extracted very easily and inexpensively. On the other hand, since the distribution is performed by the resistance value, a demerit exists in that the signal of the main transmission line is attenuated in accordance with the resistance ratio, and the signal is lost by the resistance itself.

### B) Signal Extraction Method by Directional Coupler

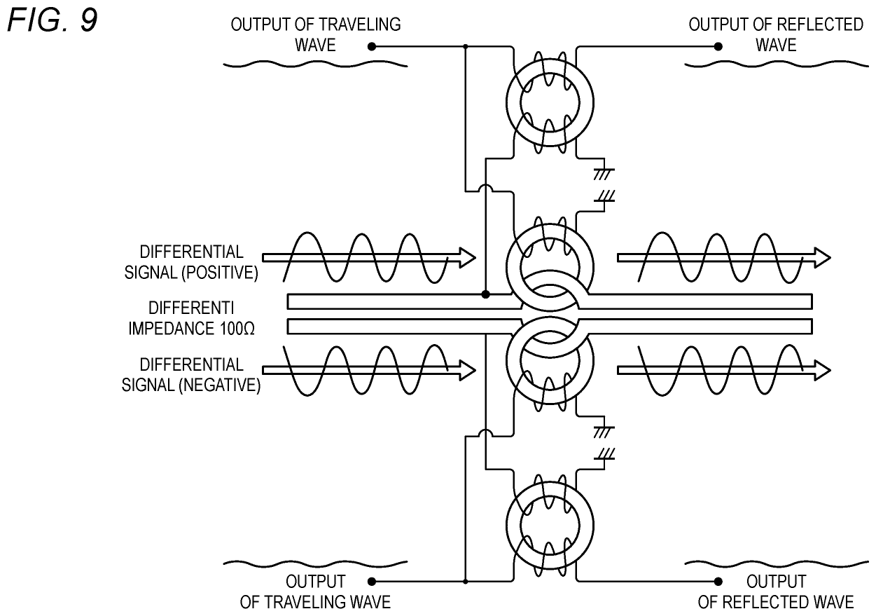

FIG. 9 is a conceptual diagram of the signal extraction by the directional coupler. The directional coupler can respectively extract a traveling wave and a reflected wave separately, and can be realized, for example, by using a ferrite core transformer. The directional coupler is used to obtain a standing wave ratio (VSWR: Voltage Standing Wave Ratio) from a ratio of transmission power to a load and reflected power thereto. Here, in the directional coupler, a signal of “the communication substrate 12→the communication substrate 13” and a signal of “the communication substrate 13→the communication substrate 12” in bidirectional communication performed between the communication substrate 12 and the communication substrate 13 are separated into a traveling wave output and a reflected wave output, after which the traveling wave output and the reflected wave output are extracted. The loss of the original signal can be minimized by using the directional coupler. The loss of the original signal is basically generated only by the loss of the ferrite core. Since isolation between an input and output end and a coupled output end can be sufficiently obtained (for example, 20 dB at a power ratio), the influence on the original signal can be reduced.

### C) Signal Extraction Method by Distributing and Combining Device

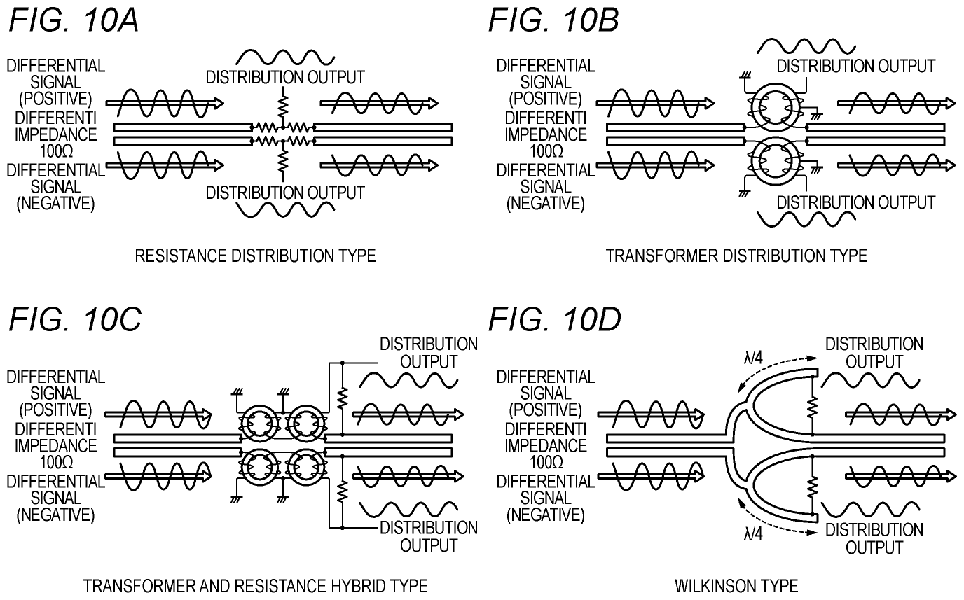

FIGS. 10A to 10D are conceptual diagrams of the signal extraction by the distributing and combining device. FIG. 10A illustrates a resistance distribution type; FIG. 10B illustrates a transformer distribution type; FIG. 10C illustrates a transformer and resistance hybrid type; and FIG. 10D illustrates a Wilkinson type. The distributing and combining devices such as a coupler, a divider, a combiner, and the like are used to divide and add signal power according to the name thereof. Since the above-described distributing and combining devices are mainly intended to distribute the signal power at a relatively close rate such as 1:1 and 1:10, the level of the original signal is significantly lowered. The resistance distribution type in FIG. 10A performs impedance matching with the resistance value and performs the distribution. In this case, a ratio of the resistance value becomes a distribution ratio. As a merit of the resistance distribution type, the resistance distribution type has a very simple structure and includes a wide band from a direct current to a high frequency. On the other hand, since the signal is lost by the resistance itself, a demerit exists in that a total amount of power after the distribution is reduced more than that before the distribution. Since isolation is hardly taken between the original signal and a separation (distribution) unit, a reverse flow and inflow of the signal caused by fluctuation of the load occur, and the characteristic is not stable. The transformer distribution type in FIG. 10B uses a transformer instead of the resistance in FIG. 10A. As a merit of the transformer distribution type, the transformer distribution type has a simple configuration and its loss such as resistance distribution is low. On the other hand, since the resistance distribution type does not include the wide band and the isolation is difficult to be taken in the same manner as that of the resistance distribution type, a demerit exists in that the characteristic is not stable. The hybrid type in FIG. 10C has a structure in which the resistance distribution type and the transformer distribution type are mixed, and as a merit thereof, the hybrid type includes the wide band, the low loss, and the high isolation. On the other hand, complication of a configuration and a cost increase by the increase of the number of components become demerits. The Wilkinson type in FIG. 10D uses a microwave transmission line pattern, thereby realizing the branching in the structure thereof. As a merit of the Wilkinson type, there is no component other than the resistance for balance and its loss is low. On the other hand, since performance depends on a width of a microstrip line and a length thereof, a demerit exists in that the Wilkinson type is a narrow band type specialized in a specific frequency band, and a measurement system thereof is enlarged because a line length becomes long depending on a frequency.

It is desirable to use the directional coupler (B) as the signal extraction method that minimizes the influence on the original signal. By using this method, since the signal of “the communication substrate 12→the communication substrate 13” and the signal of “the communication substrate 13→the communication substrate 12” can be respectively and individually extracted, a merit other than the original purpose can be obtained. Specifically, a merit exists in that this method can be used to distinguish between an abnormality included in the transmission line on the transmitter side, reflection caused by impedance mismatching due to the device failure on the receiver side, and an abnormality of a signal transmitted from the receiver side. That is, in the signal extraction using the directional coupler, it is possible to distinguish where the abnormality occurs in the front and rear places centering on an arrangement place (a signal separation position) of the directional coupler. The above-described function is mounted on the communication devices connected to both ends of the differential transmission line, such that it is possible to distinguish which device is abnormal or whether the transmission line is abnormal. Therefore, a function as a sensor of the differential transmission system can be improved.

As described above, the signal extraction method using the directional coupler according to the embodiment is applied to each measurement system according to the first to third embodiments, thereby obtaining the following effect in addition to the respective effects of the first to third embodiments. That is, when the original signal flowing through the differential transmission line is separated and extracted, the loss of the original signal can be minimized. Since it is possible to distinguish where the abnormality occurs in the front and rear places centering on the arrangement place (the signal separation position) of the directional coupler, the function as the sensor of the differential transmission system can be improved.

### Fifth Embodiment: Transmission Line Diagnostic Device

In a fifth embodiment, a cable diagnostic device to which the measurement system described in the first to fourth embodiments is applied will be described. The cable diagnostic device is a device that diagnoses a defect of a pair of differential transmission cables including two transmission lines such as twisted pair lines, and the like.

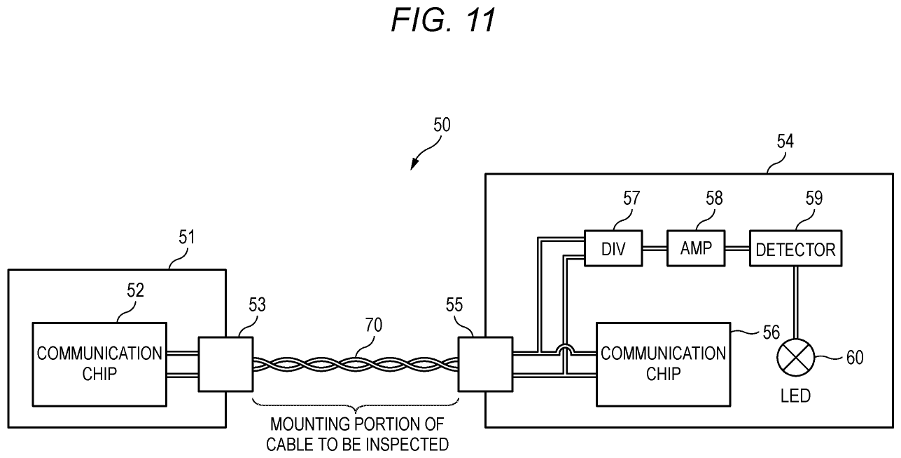

FIG. 11 is a diagram illustrating a configuration of a cable diagnostic device 50 according to a fifth embodiment. The cable diagnostic device 50 illustrated in FIG. 11 includes a substrate 51, a communication chip 52, a connector 53, a substrate 54, a connector 55, a communication chip 56, a divider 57, an amplifier 58, a detector 59, and an LED 60. The communication chip 52 and the connector 53 are provided on the substrate 51. The connector 55, the communication chip 56, the divider 57, the amplifier 58, the detector 59, and the LED 60 are provided on the substrate 54. The cable 70 which is an object to be inspected is connected between the connector 53 and the connector 55. That is, the connector 53 and the connector 55 are mounting units on which the cable 70 which is the object to be inspected is mounted.

The communication chip 52 and the communication chip 56 transmit and receive a positive signal and a negative signal whose polarities are opposite to each other via the connectors 53 and 55 and the cable 70. The divider 57 generates an in-phase signal by combining both the positive signal and the negative signal exchanged between the communication chip 52 and the communication chip 56 as they are (non-inversion). The amplifier 58 amplifies the in-phase signal generated by the divider 57. The detector 59 measures the in-phase signal amplified by the amplifier 58, and when a measured value is equal to greater than a predetermined value, the detector 59 determines that the cable is defective and then the LED 60 is turned. The LED 60 is turned on when it is determined that the cable is defective. When a change such as a change in a physical shape and a change in a material occurs in a line for transmitting the positive signal of the cable 70 or a line for transmitting the negative signal thereof, a transmission characteristic with respect to the transmission signal changes at a place (an abnormal place) where the change occurs. The positive signal and the negative signal passing through the abnormal place of the line also generate a difference in an amplitude and a phase. When the amplitude difference and the phase difference appear between the positive signal and the negative signal which are transmitted through the two transmission lines between the communication chip 52 and the communication chip 56, a slight change generated in the transmission line can be captured by measuring the amplified in-phase signal with the detector 59. The LED 60 can be turned on when the change is equal to or greater than the predetermined value.

Determining the defect of the cable (an error) when a magnitude of the detected in-phase signal is equal to or greater than the predetermined value (a threshold value) is explained in association with FIG. 5. In the in-phase signal, for example, the threshold value determined as the error may be appropriately designed in a range between a maximum amplitude value of the amplified common waveform W3 of illustrating the abnormal state and a maximum amplitude value of a common wave form having amplified the common waveform W1 of illustrating the initial state. In other words, the threshold value may be set in the range of being more than the maximum amplitude value (a voltage value) of the common waveform W1 of illustrating the initial state and being less than the maximum amplitude value (a voltage value) of the common wave form of illustrating the abnormal state, and another waveform having an amplitude value beyond the threshold vale set in a the above-described manner is determined as the error.

According to the cable diagnostic device of the embodiment, the in-phase signal obtained by combining the positive signal and the negative signal without inverting the positive and negative signals can capture a shift of the amplitude and the phase between the pair of transmission lines more than a differential signal obtained by combining the positive signal and the inverted negative signal. Therefore, the change in the transmission line can be easily detected such that a minute error can be detected. The cable diagnostic device according to the embodiment is highly versatile because the cable diagnostic device can perform diagnosis using an actual communication signal without being limited to a method using a diagnostic signal as the positive signal and the negative signal. When performing the diagnosis using the communication signal, since a communication system using a differential transmission line (a cable, and the like) which is an object to be diagnosed can be used as it is, it is not required to separately construct a diagnostic system for inputting and outputting the diagnostic signal, thereby making it possible to simplify the diagnostic system.

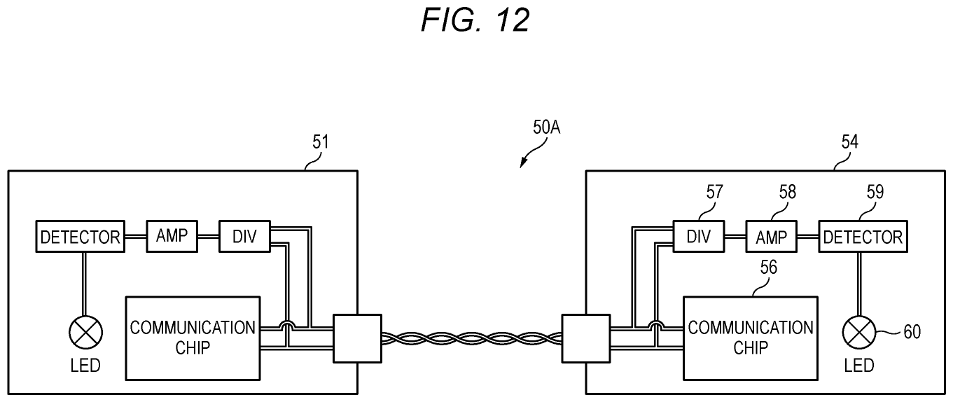

In the fifth embodiment, only one substrate 54 is provided with the divider 57, the amplifier 58, the detector 59, and the LED 60 which are components as a diagnostic unit, but the diagnostic unit may be also provided on the other substrate 51 as shown in a cable diagnostic device 50A illustrated in FIG. 12. Since an error itself of the cable 70 which is the object to be diagnosed is attenuated as the error is transmitted, the diagnosis can be performed with higher sensitivity as a detection unit (a signal extraction position from an original signal) is disposed closer to an error occurrence position. Therefore, the diagnostic accuracy can be improved by providing the diagnostic unit on both the substrates 51 and 54.

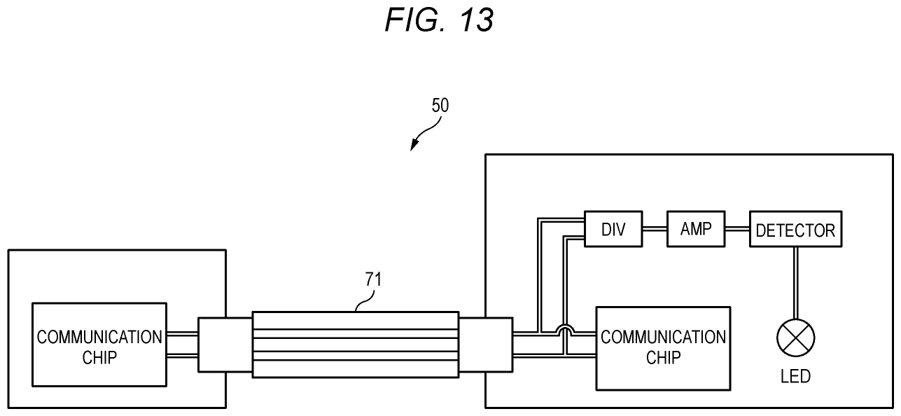

In the fifth embodiment, the twisted pair lines are used as the cable 70 which is the object to be diagnosed, but the object to be diagnosed is not limited thereto. For example, as illustrated in FIG. 13, various transmission lines related to the differential transmission such as a substrate 71 of the differential line can be used as the object to be diagnosed.

### Sixth Embodiment: Transmission Line Diagnostic Device

In the cable diagnostic device 50 according to the fifth embodiment illustrated in FIG. 11, when performing the shipping inspection of the twisted pair lines, any one of the twisted lines usually has a high possibility of causing a defect (an error), and even though both of the twisted lines are defective, a possibility that degrees of the defects thereof are exactly the same as each other is low. However, when the errors generated in the two transmission lines accidentally become the same as each other and no phase difference therebetween occurs, there is a possibility of erroneously performing the diagnosis. Even in this case, a cable diagnostic device capable of detecting the error will be described in a sixth embodiment.

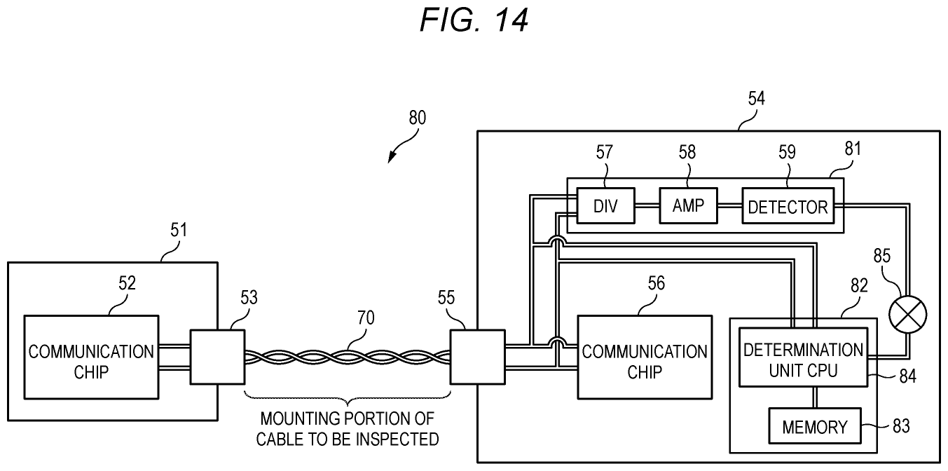

FIG. 14 is a diagram illustrating a cable diagnostic device 80 according to the sixth embodiment. In the cable diagnostic device 80 according to the sixth embodiment and the cable diagnostic device 50 according to the fifth embodiment in FIG. 11, a configuration for executing the same function will be denoted by the same reference sign, and the redundant description thereof will be omitted. The cable diagnostic device 80 includes a common mode detection unit 81 and an amplitude change detection unit 82 provided on a substrate 54. The common mode detection unit 81 includes the divider 57, the amplifier 58, and the detector 59. The amplitude change detection unit 82 includes a memory 83 and a determination unit CPU 84. The memory 83 stores data of a cable having a normal characteristic in advance. The determination unit CPU 84 detects and monitors an amplitude level itself of a signal being communicated. That is, the determination unit CPU 84 detects an amplitude change level of a differential signal obtained by combining a positive signal and a negative signal transmitted through the cable 70, one of which is inverted, and then compares the amplitude change level thereof with the data of the cable having the normal characteristic stored in the memory 83. Next, when a difference equal to or greater than a threshold value (a threshold value for an amplitude change) exists between the two, the determination unit CPU 84 determines an error. The LED 85 is turned on when the error is determined by either one of the detector 59 of the common mode detection unit 81 and the determination unit CPU 84 of the amplitude change detection unit 82.

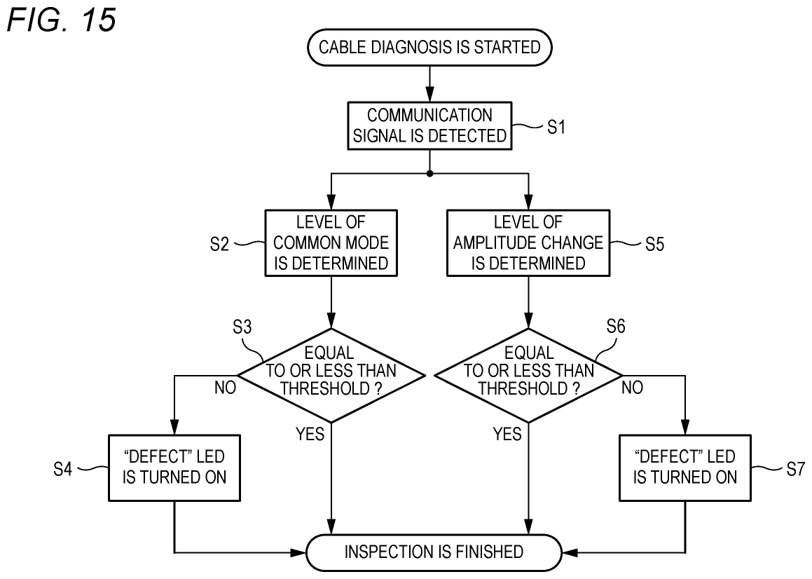

FIG. 15 is a diagram illustrating a flow of cable defect diagnosis in the cable diagnostic device 80 according to the sixth embodiment. When a cable which is an object to be inspected is mounted on the cable diagnostic device 80 and cable diagnosis is started, the common mode detection unit 81 and the amplitude change detection unit 82 respectively extract the positive signal and the negative signal (a communication signal) (step S1), and proceeds to the following processing. The common mode detection unit 81 determines a level of the in-phase signal detected by the detector 59 (step S2), and determines whether the level of the in-phase signal is equal to or less than a threshold value for the in-phase signal (step S3). In step S3, when the level of the in-phase signal is not equal to or less than the threshold value for the in-phase signal, the common mode detection unit 81 determines that “the cable is defective”, and then the LED 85 is turned on (step S4), whereas when the level of the in-phase signal is equal to or less than the threshold value for the in-phase signal, the common mode detection unit 81 determines that the cable is normal and then terminates the inspection. On the other hand, the amplitude change detection unit 82 determines an amplitude change of the differential signal (step S5), and determines whether the amplitude change of the differential signal is equal to or less than a threshold value for the amplitude change (step S6). In step S6, when the amplitude change of the differential signal is not equal to or less than the threshold value for the amplitude change, the amplitude change detection unit 82 determines that “the cable is defective”, and then the LED 85 is turned on (step S7), whereas when the amplitude change of the differential signal is equal to or less than the threshold value for the amplitude change, the amplitude change detection unit 82 determines that the cable is normal and then terminates the inspection. The threshold value for the in-phase signal and the threshold value for the amplitude change are determined for each inspection object at each time of diagnosis.

According to the cable diagnostic device 80 of the embodiment, the two detection units of the common mode detection unit 81 and the amplitude change detection unit 82 are provided, and whether the cable is defective is determined in parallel, whereby the following effect is obtained in addition to the effect of the fifth embodiment. That is, even when the defects of the same degree are simultaneously generated in the two transmission lines forming the differential transmission line, the defect can be detected as an error by comparison with the data of the normal characteristic. Therefore, the high accuracy of diagnosis can be achieved.

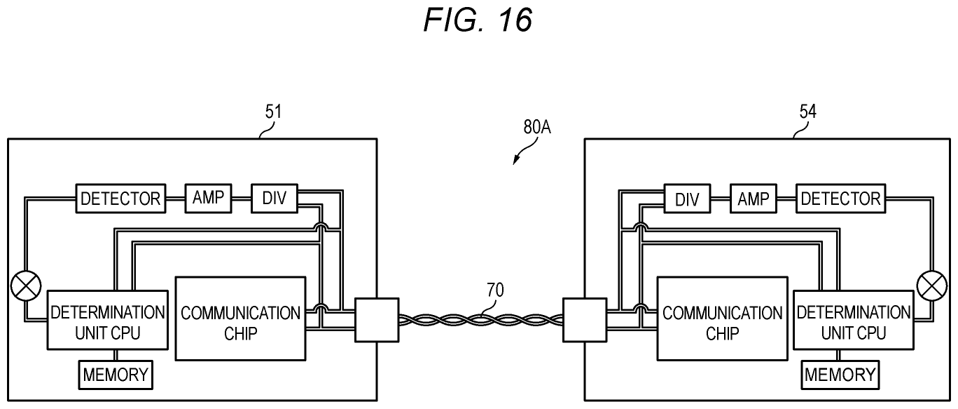

In the sixth embodiment, only one substrate 54 is provided with the common mode detection unit 81, the amplitude change detection unit 82, and the LED 85 which are components as a diagnostic unit, but as illustrated in FIG. 16, the diagnostic unit may be also provided on the other substrate 51. Since an error itself of the cable 70 which an object to be diagnosed is attenuated as the error is transmitted, the diagnosis can be performed with higher sensitivity as a detection unit (a signal extraction position from an original signal) is disposed closer to an error occurrence position. Therefore, the diagnostic accuracy can be improved by providing the diagnostic unit on both the substrates 51 and 54.

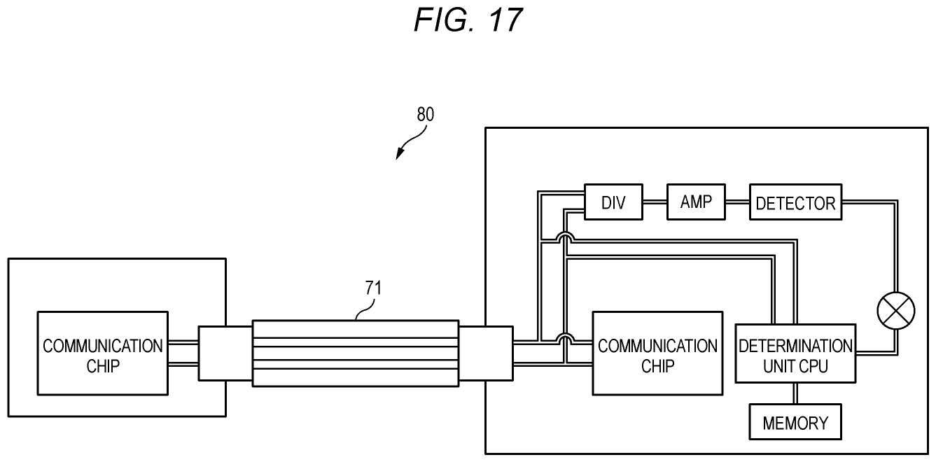

In the sixth embodiment, the twisted pair lines are used as the cable 70 which is the object to be diagnosed, but the object to be diagnosed is not limited thereto. For example, as illustrated in FIG. 17, various transmission lines related to the differential transmission such as the substrate 71 of the differential line can be used as the object to be diagnosed.

### Seventh Embodiment: Liquid Level Detection Device

In a seventh embodiment, a liquid level detection device to which the measurement systems described in the first to fourth embodiments are applied will be described.

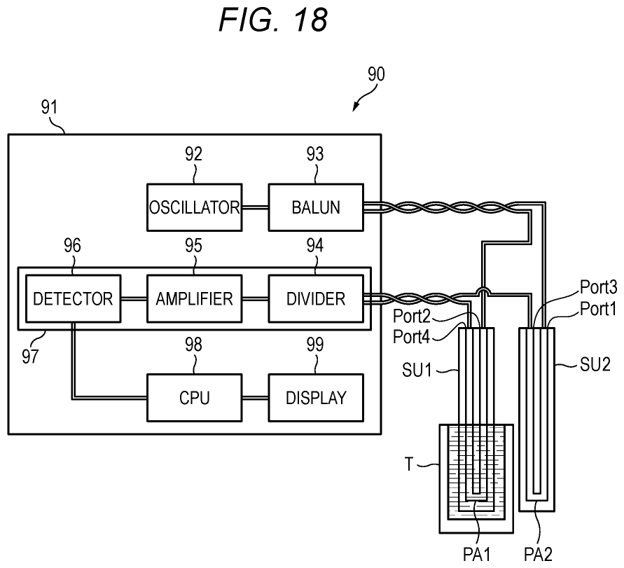

FIG. 18 is a diagram illustrating a configuration of a liquid level detection device 90 of the seventh embodiment. The liquid level detection device 90 illustrated in FIG. 18 is formed of a sensor unit and a determination unit 91. The sensor unit includes two substrates SU1 and SU2 of the same shape respectively provided with patterns PA1 and PA2 (a first line and a second line) formed by folding back a straight-line path. The substrate SU1 is treated as a substrate for detecting a liquid level (hereinafter, also referred to as a liquid level detection substrate SU1). The substrate SU2 is treated as a reference substrate for correction (hereinafter, also referred to as a reference substrate SU2). The determination unit 91 includes an oscillator 92, a balun 93, a common mode detection unit 97 including a divider 94, an amplifier 95, and a detector 96, a CPU 98, and a display 99. The substrate SU1 is installed in a tank T which is a measured object, and the substrate SU2 is installed outside (near) the tank T.

The oscillator 92 generates a signal for the diagnosis. The balun 93 forms a differential signal, that is, a positive signal and a negative signal whose polarities are opposite to each other from the output of the oscillator 92. The positive signal and the negative signal outputted from the balun 93 are inputted to the liquid level detection substrate SU1 and the reference substrate SU2. In the reference substrate SU2, the positive signal is inputted from a port 1 to the pattern PA2, outputted from a port 3, and inputted to the divider 94. In the liquid level detection substrate SU1, the negative signal is inputted from a port 2 to the pattern PA1, outputted from a port 4, and inputted to the divider 94. The divider 94 generates an in-phase signal (a common mode signal) by combining both the positive signal and the negative signal passing through the substrates SU1 and SU2 as they are (non-inversion). A level of the in-phase signal corresponds to a liquid level in the tank T as described later. The amplifier 95 amplifies the in-phase signal generated by the divider 94. A minute change in the liquid level can be easily detected by amplifying the in-phase signal. The detector 96 measures the in-phase signal amplified by the amplifier 95. The CPU 98 calculates the liquid level from a measurement result of the in-phase signal. The display 99 displays the calculated liquid level.

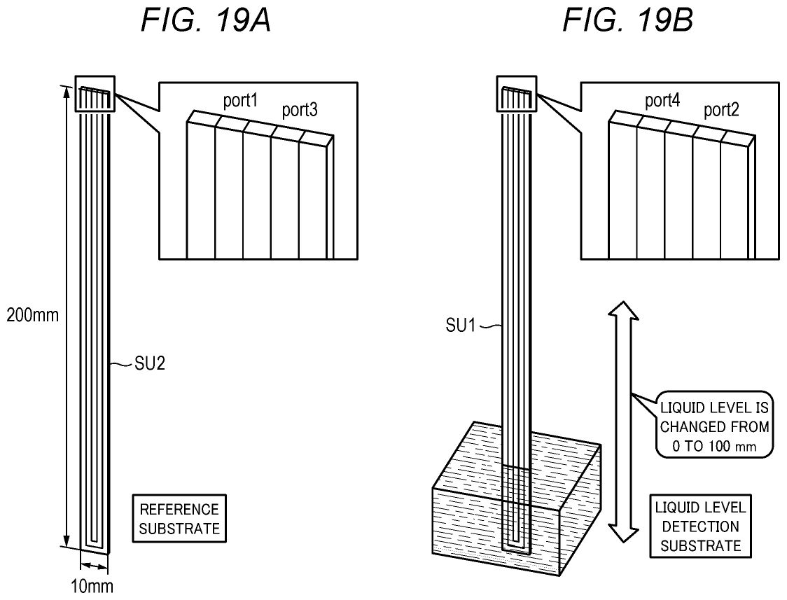

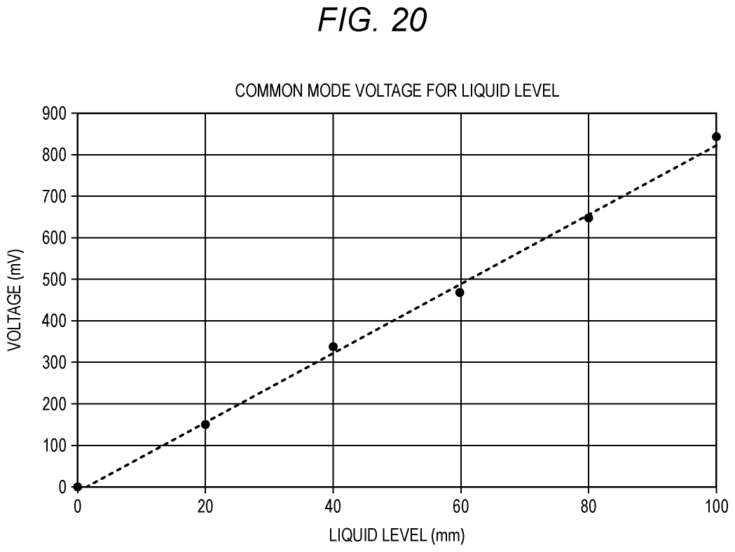

FIGS. 19A and 19B are diagrams illustrating a simulation model of the sensor unit. A three-dimensional electromagnetic field simulation model of the reference substrate SU2 and the liquid level detection substrate SU1 illustrated in FIGS. 19A and 19B is generated, and a transmission characteristic of when the liquid level is changed is analyzed. The sensor unit is a fr4 substrate having a Cu pattern of 1 mm width. As a liquid which is a measured object, a liquid having a dielectric constant 3 assuming gasoline is set. The transmission characteristic obtained by electromagnetic field analysis using the simulation model is incorporated into a sensor characteristic of a circuit simulator model from which only the common mode detection unit 97 is taken out, and a common mode voltage change with respect to a liquid level change is analyzed. A detection signal uses a differential sine wave of Vₚ₋ₚ100 mV at 100 MHz. A simulation result is illustrated in FIG. 20.

FIG. 20 is a diagram illustrating a simulation result using the model illustrated in FIGS. 19A and 19B. FIG. 20 illustrates the common mode voltage change when the liquid level is changed to 0, 20, 40, 60, 80, and 100 mm. FIG. 20 can confirm a result indicating that the common mode voltage linearly changes according to the change of the liquid level. If the simulation result is stored in advance as a table, the CPU 98 can easily calculate the liquid level from the measurement result of the detector 96 with reference to the table.

According to the liquid level detection device 90 of the embodiment, the substrate SU1 is installed in the tank T which is the measured object for performing the liquid level detection and the substrate SU2 is used as the reference for the correction, such that a difference corresponding to the liquid level in the tank T appears as the level of the in-phase signal. That is, since the phase change can be detected instead of the amplitude change of the positive signal and the negative signal, the liquid level can be detected with high accuracy. Since the sensor is not a capacitance detection type sensor in a related art, a straight-line pattern is sufficient, and since a comb-teeth type pattern for providing the capacitance to the substrate of the sensor unit is not required, a sensor shape can be slimmed.

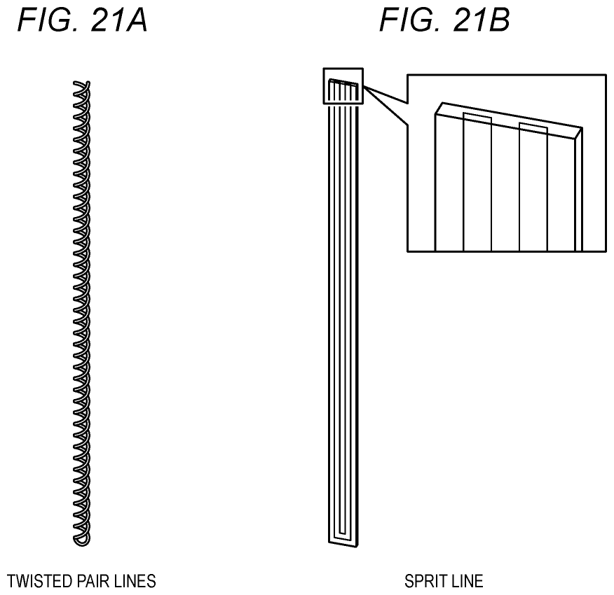

In the seventh embodiment, the substrates SU1 and SU2 including the patterns PA1 and PA2 formed by folding back the straight-line path are used as the sensor unit, but twisted pair lines illustrated in FIG. 21A or a strip line illustrated in FIG. 21B may be used. Alternatively, any medium capable of performing signal transmission such as a flat line, an FPC, and the like can be applied as the sensor unit.

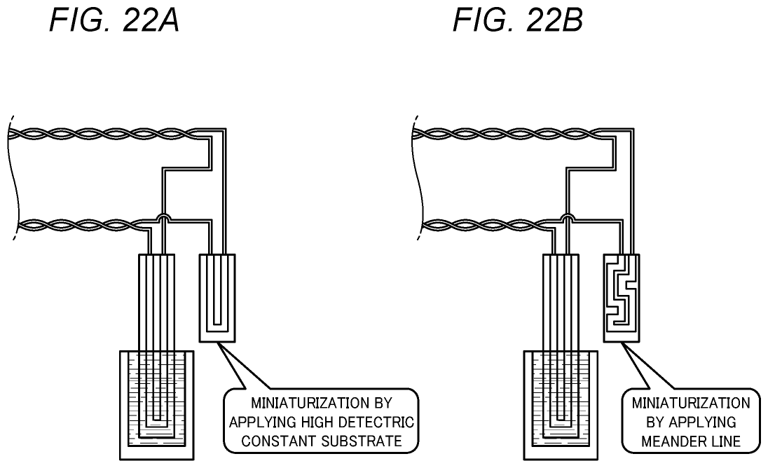

In the seventh embodiment, the substrates SU1 and SU2 of the same shape are used as the liquid level detection substrate and the reference substrate, but the reference substrate may be any substrate capable of performing the signal transmission at the same speed and time as the liquid level detection substrate. Therefore, even though line shapes are not the same as each other, the reference substrate can be miniaturized by applying a high dielectric constant substrate illustrated in FIG. 22A and a meander line illustrated in FIG. 22B and by designing a pattern and an electrical length of the liquid level detection substrate to become equal in length.

### Eighth Embodiment: Liquid Level Detection Device

In the liquid level detection device 90 according to the seventh embodiment illustrated in FIG. 18, since a U-shaped reciprocating line portion of the line of the sensor unit is used for detecting the liquid level (disposed inside the liquid), a width in the short direction (horizontal width) needs the reciprocating line portion and takes up a space. In the liquid level detection device 90 according to the seventh embodiment, when the liquid solution which is a liquid level detection target is changed, for example, when a dielectric constant becomes low, a change from a reference becomes small, such that adjustment may be difficult in some cases even though a common (in-phase signal) output value decreases and detection becomes difficult. In the eighth embodiment, a liquid level detection device capable of eliminating these problems will be described.

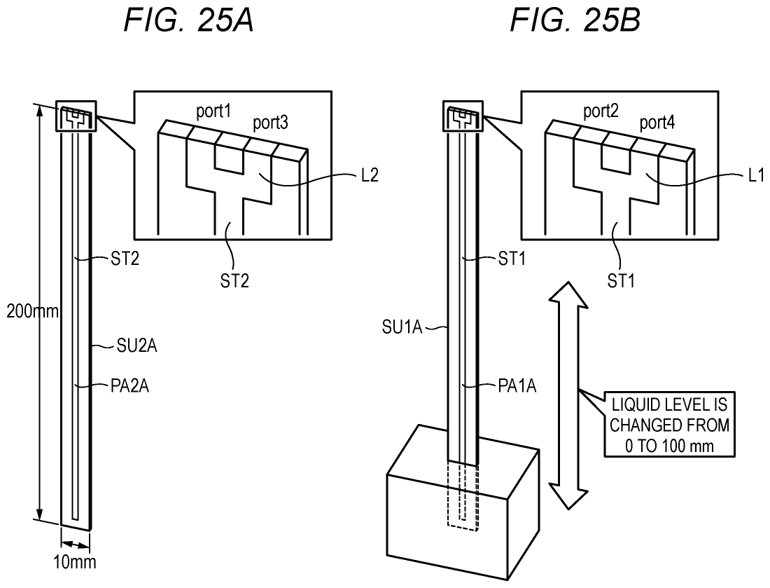

The liquid level detection device 90 according to the eighth embodiment includes two substrates SU1A and SU2A of the same shape instead of the substrates SU1 and SU2 in the liquid level detection device 90 according to the seventh embodiment illustrated in FIG. 18. As illustrated in FIGS. 25A and 25B, the substrates SU1A and SU2A are formed by respectively changing the sensor patterns PA1 and PA2 on the substrates SU1 and SU2 to patterns PA1A and PA2A. Since other configurations of the liquid level detection device 90 according to the eighth embodiment are described hereinabove, the redundant description thereof will be omitted.

FIGS. 25A and 25B are diagrams illustrating a simulation model of a sensor unit in the liquid level detection device 90 according to the eighth embodiment. The patterns PA1A and PA2A of the embodiment have shapes in which open stubs ST1 and ST2 are respectively provided on input and output passing lines L1 (line from port 2 to port 4) and L2 (line from port 1 to port 3) on the upper part of the substrates SUA1 and SUA2. In the embodiment, the input and output passing lines L1 and L2 are not used for sensing the liquid level but the open stubs ST1 and ST2 are used for detecting the liquid level.

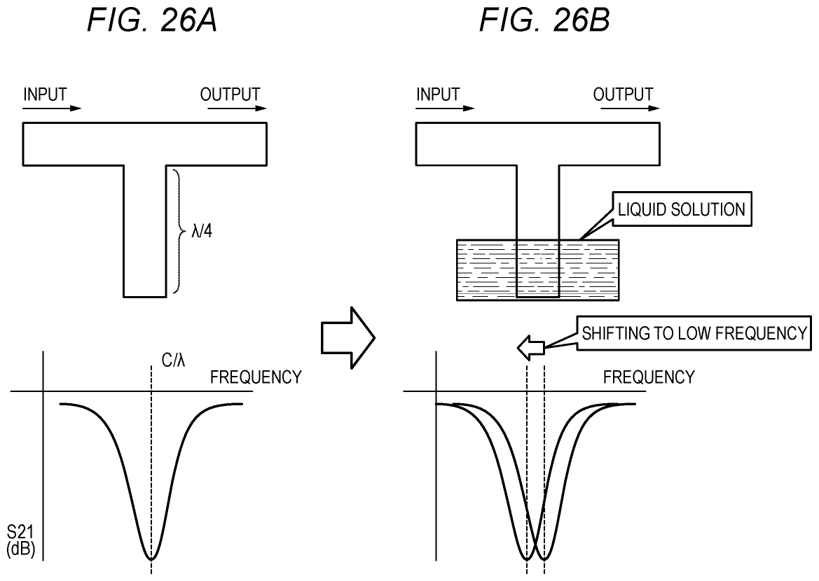

FIGS. 26A and 26B are diagram illustrating the measurement principle of the liquid level detection device 90 according to the eighth embodiment, and indicating a change in frequency characteristics in the open stubs ST1 and ST2. When a high frequency signal is transmitted to the line including the open stub, there is a characteristic that the high frequency signal performs an electrical short action at a frequency of wavelength λ in which a stub length is λ/4 (FIG. 26A). At this time, the signal becomes an image flowing in the stub direction; a passing characteristic (S21 parameter) of the input signal deteriorates; and a valley characteristic is indicated as illustrated in FIGS. 26A and 26B. Here, when the stub portion is immersed in the liquid solution which is the liquid level detection target, the stub length becomes electrically extended according to a length immersed in the liquid solution, whereby a frequency whose passing characteristic deteriorates moves to a low frequency side (FIG. 26B). That is, since the change in the passing characteristic when performing detection at a certain specific frequency is synonymous with the change in the signal level and the occurrence of the phase change, the liquid level can be detected by the common mode (in-phase signal) voltage change at this time.

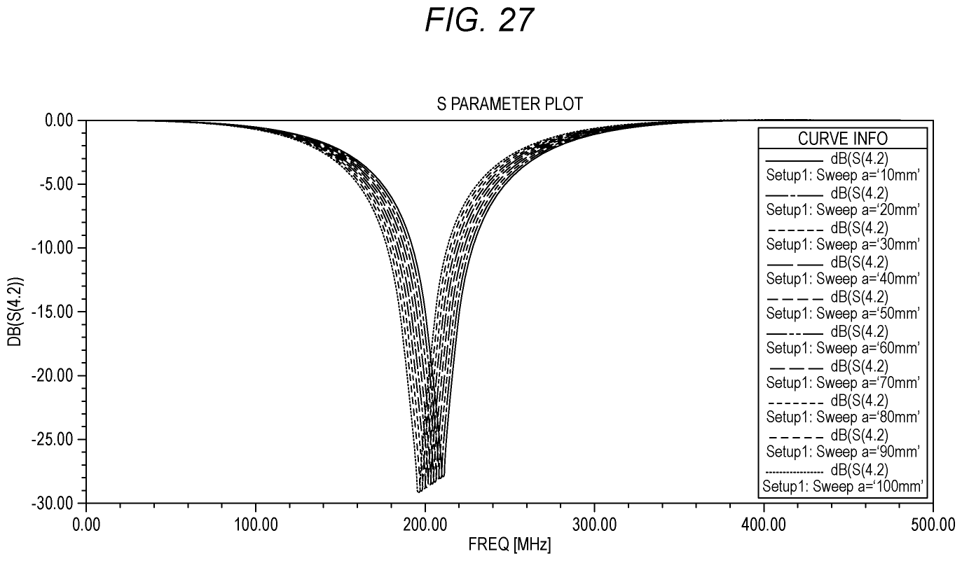

FIG. 27 is a diagram illustrating a frequency characteristic result with respect to a change in a liquid level by the simulation using the model illustrated in FIGS. 25A and 25B, and indicating a passing characteristic result when the liquid level is changed in a range of 1 to 100 mm. From FIG. 27, it can be seen that the frequency characteristics move to the low frequency side as the liquid level rises.

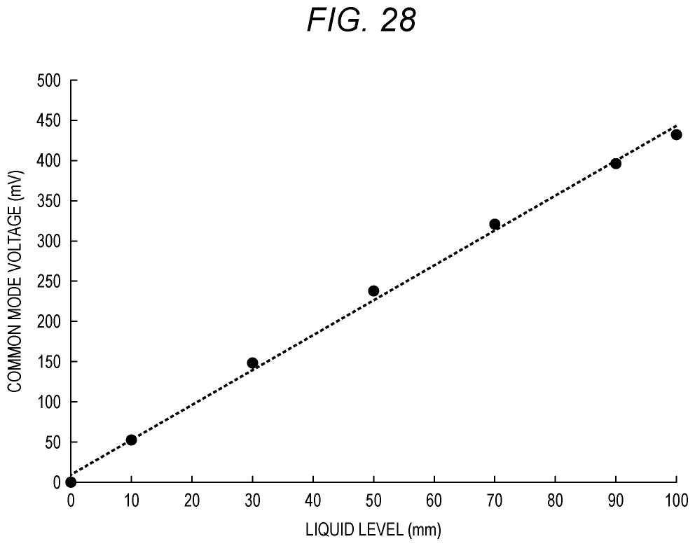

FIG. 28 is a diagram illustrating a simulation result using the model illustrated in FIGS. 25A and 25B, and indicating a result of inserting a sensor characteristic indicating the result of FIG. 27 into a common mode detection circuit and graphing a common mode voltage value with respect to the liquid level. From FIG. 28, it can be seen that the voltage value rises linearly as the liquid level rises, and the liquid level can be detected from the voltage value. The liquid level detection device 90 of the embodiment has a characteristic that sensitivity can be changed when a frequency to be sensed is changed. FIG. 28 is a detection result when a signal of 100 MHz is inputted, but since the change in frequency characteristics is larger at 100 MHz or higher according to the result indicated in FIG. 27, improvement in detection sensitivity is assumed. Therefore, even when the liquid solution which is the liquid level detection target is changed to a liquid solution having a different dielectric constant, sensitivity adjustment can be performed.

The liquid level detection device 90 of the embodiment generates a signal difference according to a change in a liquid level position as the in-phase signal by using the open stubs ST1 and ST2 provided on the input and output lines L1 and L2, thereby detecting the liquid level position. According to the configuration described above, in addition to the effect of the seventh embodiment, compact and highly accurate liquid level measurement can be performed. That is, since the liquid level can be detected only by the open stubs ST1 and ST2 (one line), the sensor element can be slimmed. Thus, it is possible to detect a liquid level such as a calorimeter. A detection frequency is adjusted for the liquid level detection target, such as a liquid solution having a low dielectric constant, in which a change from the reference is small and thus it is difficult to detect the in-phase signal, whereby sensor sensitivity can be improved and a sensor level can be detected.

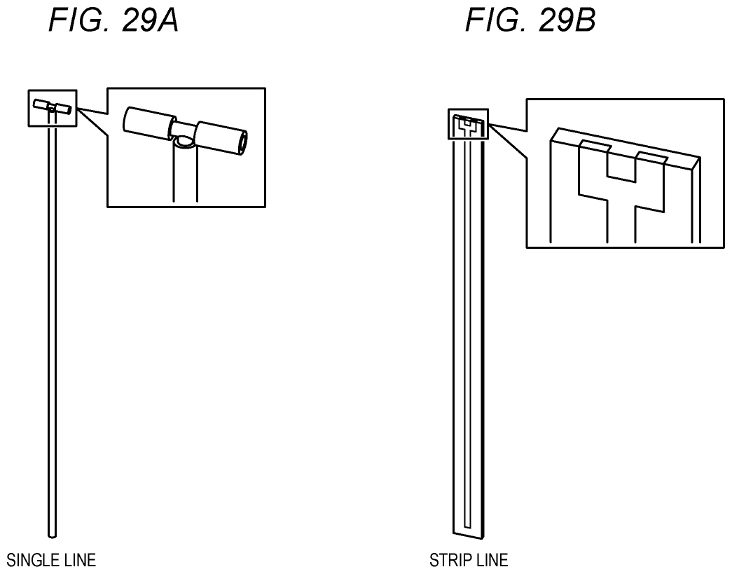

In the eighth embodiment, the substrates SU1A and SU2A having the patterns PA1A and PA2A including the open stubs ST1 and ST2 in a straight line are used as the sensor units, but a single line illustrated in FIG. 29A and a strip line illustrated in FIG. 29B may be used. Alternatively, any medium capable of performing the signal transmission such as a twisted pair line, a flat line, and an FPC can be applied as the sensor unit.

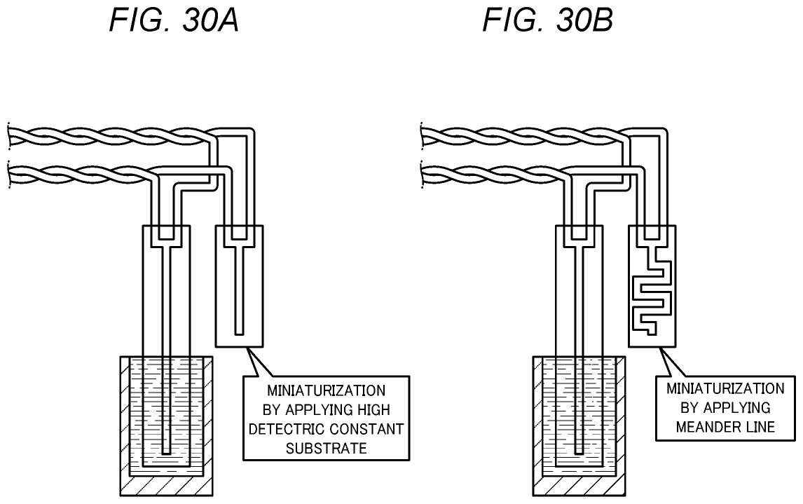

In the eighth embodiment, the substrates SU1A and SU2A of the same shape are used as the liquid level detection substrate and the reference substrate, but the reference substrate may be any substrate capable of performing the signal transmission at the same speed and time as the liquid level detection substrate. Therefore, even though the line shapes are not the same as each other, the reference substrate can be miniaturized by applying a high dielectric constant substrate illustrated in FIG. 30A and a meander line illustrated in FIG. 30B and by designing the pattern and the electrical length of the liquid level detection substrate to become equal in length.

### Ninth Embodiment: Displacement Detection Device

As a displacement sensor that performs position detection, for example, disclosed is a device in which an induced voltage caused by an eddy current generated in a metal plate of a measured object is detected by a receiving coil, and position information is outputted by comparing the induced voltage with information stored in a memory (refer to JP 2016-001123 A). In the displacement sensor, variations in measured values caused by a change in a surrounding environment such as a temperature change are assumed, such that there is a problem in measurement accuracy. In the displacement sensor, measurement sensitivity may vary depending on a size of a measurement object and a sensor distance, but it is difficult to adjust the measurement sensitivity. In the ninth embodiment, a non-contact displacement detection device capable of solving these problems will be described. The non-contact displacement detection device according to the ninth embodiment is a displacement detection device to which the measurement system described in the first to fourth embodiments is applied.

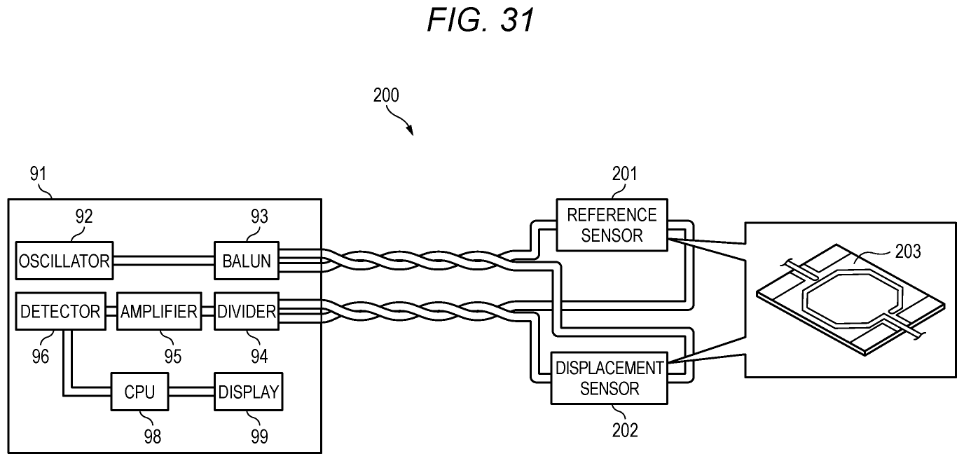

FIG. 31 is a diagram illustrating a configuration of a displacement detection device 200 according to the ninth embodiment. The displacement detection device 200 in FIG. 31 is formed by changing the sensor unit in the liquid level detection device 90 in FIG. 18. In the displacement detection device 200 in FIG. 31 and the liquid level detection device 90 in FIG. 18, a configuration for executing the same function will be denoted by the same reference sign, and the redundant description thereof will be omitted. The displacement detection device 200 illustrated in FIG. 31 is configured with the sensor unit and the determination unit 91. The sensor unit illustrated in FIG. 31 includes a reference sensor 201 and a displacement sensor 202 to which a one-and-a-half loop coil 203 formed of a substrate is applied. The CPU 98 calculates a displacement level from the measurement result of the in-phase signal, and the calculated displacement level is displayed on the display 99. That is, in the ninth embodiment, a signal difference according to a change in position when a metallic block which is a device under test (DUT) approaches the displacement sensor 202 is generated as the in-phase signal, and the position can be detected in a non-contact manner.

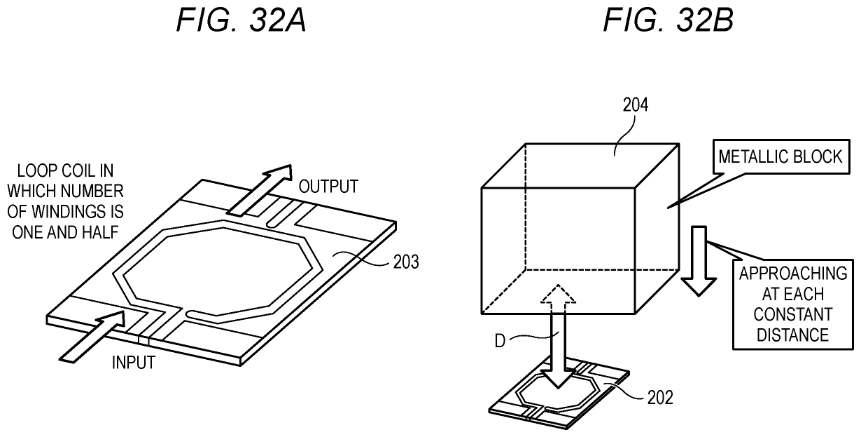

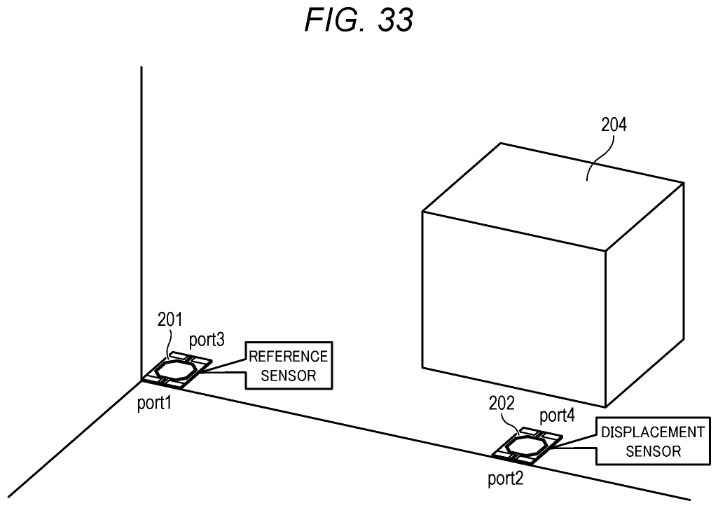

FIGS. 32A and 32B is a diagram illustrating a simulation model of the sensor unit in the displacement detection device 200 according to the ninth embodiment, and FIG. 33 is a diagram illustrating the measurement principle of the displacement detection device according to the ninth embodiment. As illustrated in FIG. 32A, as a sensor model, the one-and-a-half loop coil 203 is used. The metallic block 204 is placed close to the displacement sensor 202 at a frequency at which radiation is generated, and frequency characteristics (S21 characteristics) when a distance D between the displacement sensor 202 and the metallic block 204 is changed is analyzed. As a simulation model, as illustrated in FIG. 33, sensors of the same shape are prepared, and one is used as the reference sensor 201 and the other is used as the displacement sensor 202. A difference in coil characteristics is generated with respect to the reference sensor 201 according to the distance D between the displacement sensor 202 and the metallic block 204. The displacement detection device 200 generates and detects the difference therebetween as the in-phase signal. As the metallic block 204 approaches the displacement sensor 202, generated magnetic fields from the coil (one-and-a-half loop coil 203) are interlinked, and an eddy current is generated in the metallic block 204. The generated magnetic field affects a coil inductance characteristic.

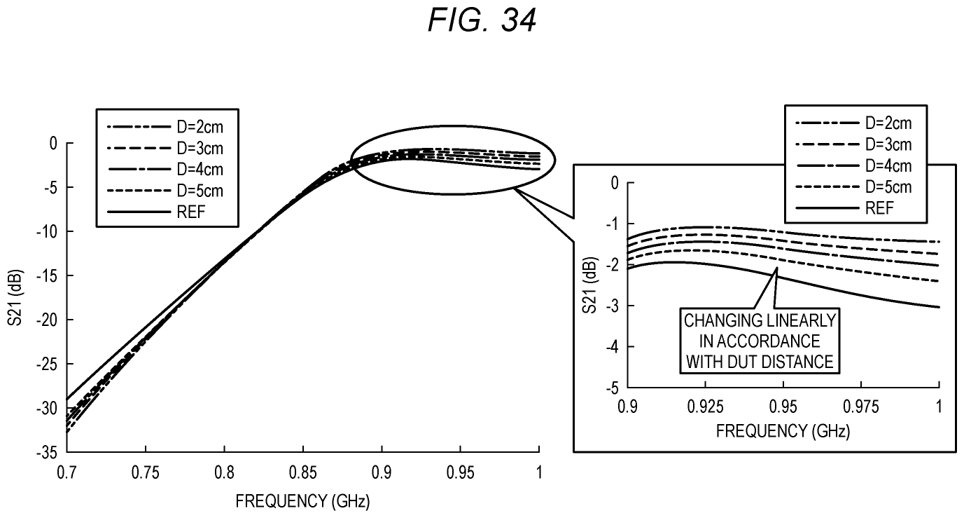

FIG. 34 is a diagram illustrating a change in frequency characteristics (S21 characteristics) according to the change in the distance of the metallic block 204 illustrated in FIG. 33. According to FIG. 34, it can be seen that the S21 characteristics tend to improve as the metallic block 204 approaches the displacement sensor 202. This is considered to be because the impedance is changed in a matching direction thereof due to a change in the inductance of the coil. According to FIG. 34, it is indicated that the S21 characteristics linearly change according to the distance D between the displacement sensor 202 and the metallic block 204, and the position detection can be performed.

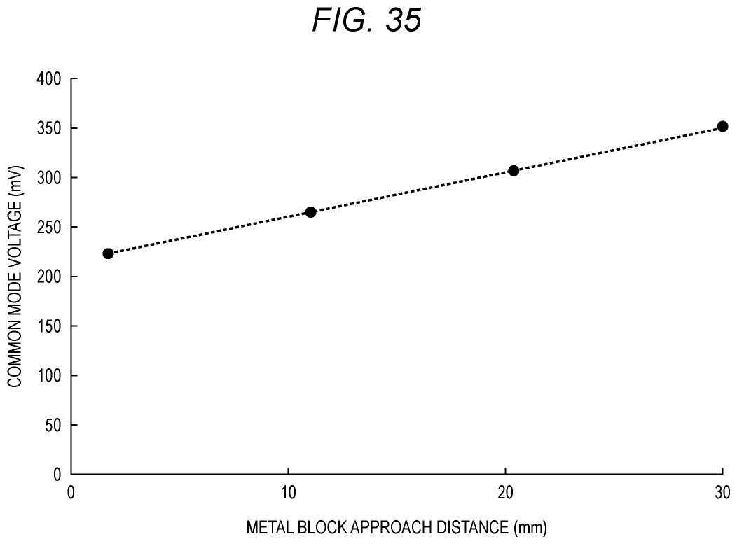

FIG. 35 is a diagram illustrating a simulation result using the model illustrated in FIGS. 32A and 32B, and indicating a result of a simulation performed by incorporating an electromagnetic field analysis result illustrated in FIG. 34 into the sensor unit (reference sensor 201 and displacement sensor 202) illustrated in FIG. 31. The detection signal uses a differential sine wave of Vₚ₋ₚ100 mV at 900 MHz. The reason why the detection frequency is set to 900 MHz is that a difference in the frequency characteristics with respect to the change in the distance D linearly changes in the result of FIG. 34. As illustrated in FIG. 35, the common mode voltage when the distance D therebetween is caused to be closer by 10 mm linearly increases. The reason why a voltage is generated when the distance D is zero is that the voltage of a change depending on the presence or absence of the metallic block 204 is generated in comparison with the reference sensor 201 where the metallic block 204 is not placed.

According to the displacement detection device 200 of the embodiment, since the displacement is detected by comparison with the reference, it is possible not only to reduce the influence of an error factor such as an external environment, but also to perform highly accurate measurement. The sensitivity adjustment of the sensor can be performed without changing the shape of the sensor by adjusting the detection frequency. Since an object can be detected in a non-contact manner, a wide range of application such as a human sensor and a pet sensor can be performed.

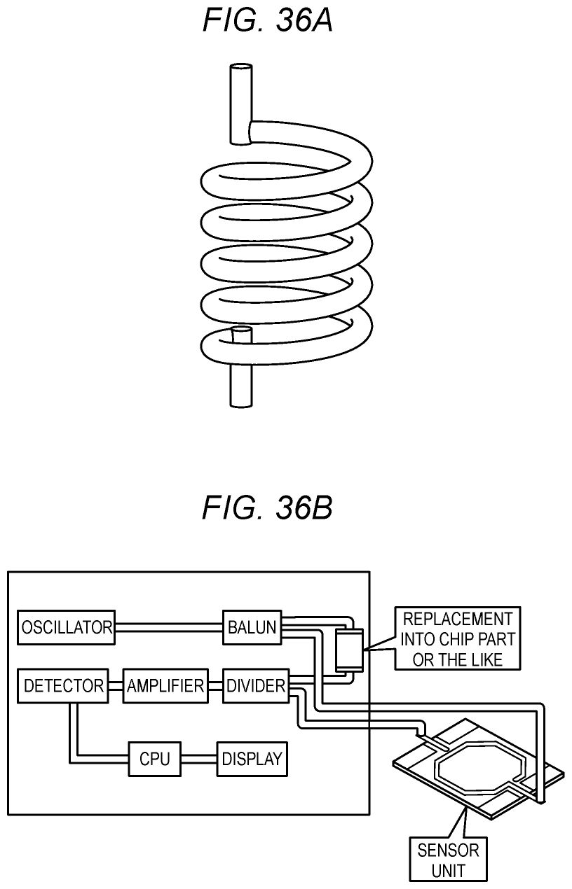

In the ninth embodiment, the one-and-half loop coil 203 is used as the sensor unit, but a solenoid coil may be applied as illustrated in FIG. 36A in addition to the coil formed by the substrate. By using the solenoid coil, a displacement sensor having high sensitivity in the central axis direction can be realized. As illustrated in FIG. 36B, the reference sensor 201 can be replaced with a chip part such as a capacitor, thereby simplifying the sensor.

### Tenth Embodiment: Pressure Detection Device

As a pressure sensor that detects pressure, for example, disclosed is a pressure sensor including a piezoelectric vibrator and an excitation electrode fixed to a diaphragm and generating stress according to the deflection (refer to JP 2011-137746 A). The pressure sensor derives a pressure value according to a value of the frequency because an oscillation frequency of the piezoelectric vibrator changes by the stress applied to the diaphragm. The pressure sensor has a complicated structure using the piezoelectric vibrator and is sandwiched between electrodes, and it is assumed that it is difficult to obtain a reasonable result while maintaining the sensitivity in consideration of the influence of a use environment and deterioration caused by use time. The pressure sensor has a difficulty) in adjusting the sensitivity with respect to variation factors such as a change in a target whose pressure is to be detected and an environment factor. In the tenth embodiment, a pressure detection device capable of solving these problems will be described. The pressure detection device according to the tenth embodiment is a pressure detection device to which the measurement system described in the first to fourth embodiments is applied.

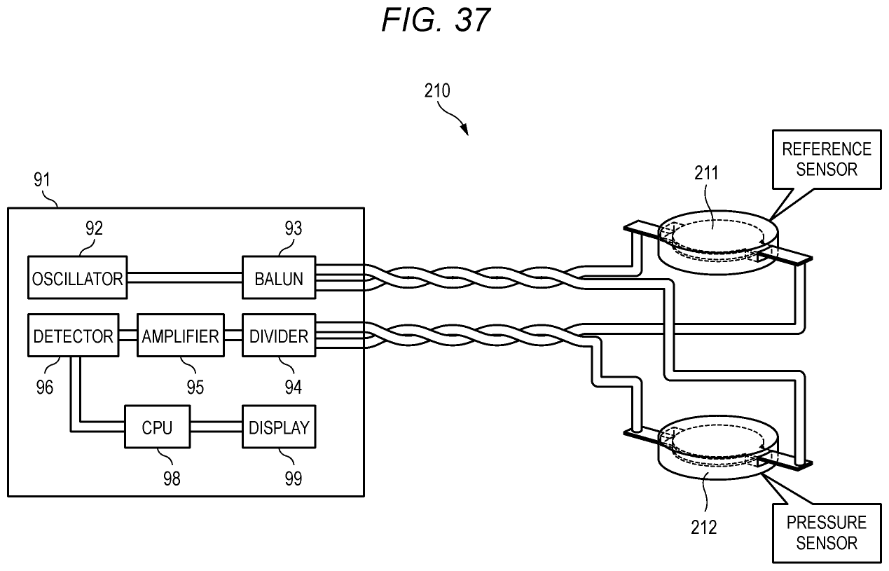

FIG. 37 is a diagram illustrating a configuration of a pressure detection device 210 according to the tenth embodiment. The pressure detection device 210 in FIG. 37 is formed by changing the sensor unit in the liquid level detection device 90 in FIG. 18. In the pressure detection device 210 in FIG. 37 and the liquid level detection 90 in FIG. 18, a configuration for executing the same function will be denoted by the same reference sign, and the redundant description thereof will be omitted. The pressure detection device 210 illustrated in FIG. 37 is configured with the sensor unit and the determination unit 91. The sensor unit in FIG. 37 includes a reference sensor 211 and a pressure sensor 212. The CPU 98 calculates a level such as pressure and stress from the measurement result of the in-phase signal, and the calculated level is displayed on the display 99. That is, in the tenth embodiment, a signal difference according to a change in pressure applied to the pressure sensor is generated as the in-phase signal, and the change in pressure can be detected.

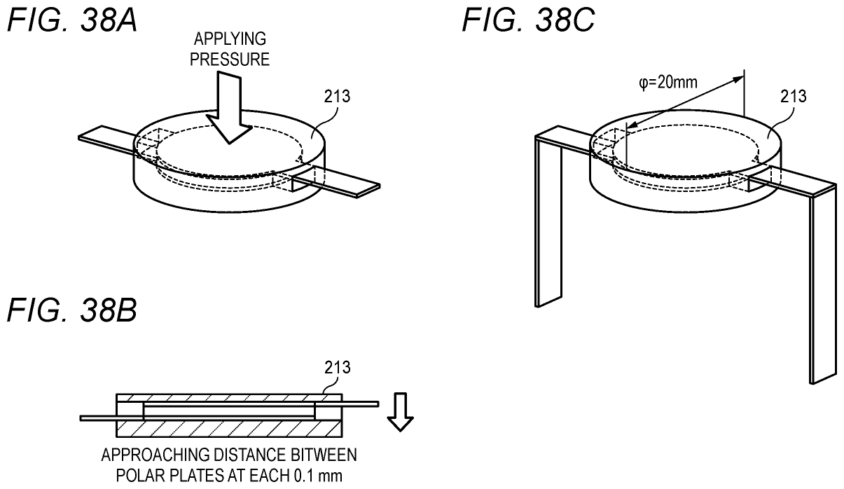

FIGS. 38A to 38C are diagrams illustrating a simulation model of the sensor unit in the pressure detection device 210 according to the tenth embodiment, and also illustrates a change parameter by pressurization. As an example of a sensor shape, here, an example of a sensor 213 in which electrode plates having a diameter of 20 mm are opposite to each other at a space of 1 mm and covered with a diaphragm will be described. In the simulation, the frequency characteristics (S21 characteristics) when a space between the electrode plates is narrowed by 0.1 mm by applying pressure to the sensor 213 are analyzed.

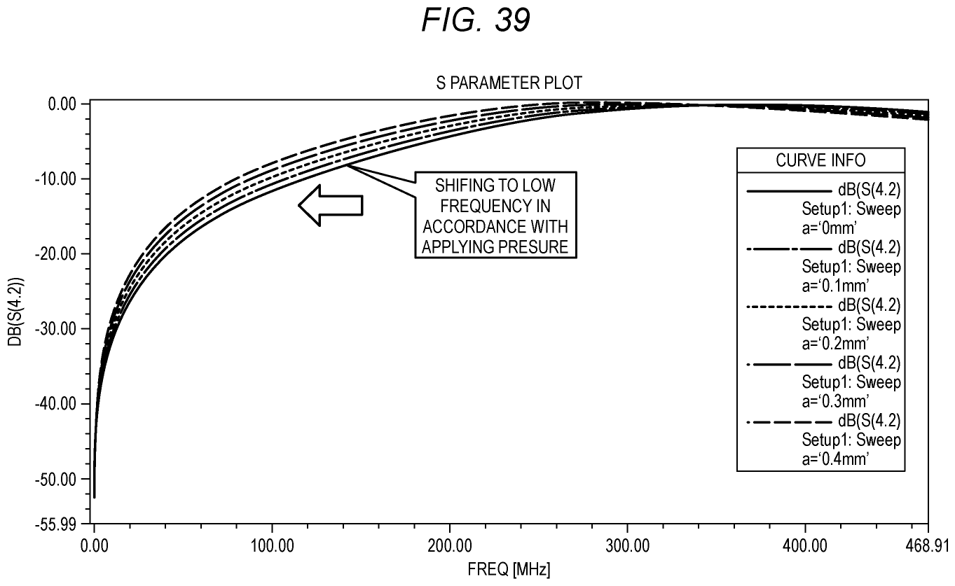

FIG. 39 is a diagram illustrating a change in frequency characteristics according to a change in the space between the electrode plates (a change in pressure) illustrated in FIGS. 38A to 38C. Since capacitance increases as the electrode plates come closer to each other, a cut-off frequency of a passing signal moves to the low frequency side, and the frequency characteristics of S21 changes. According to FIG. 39, it can be seen that the frequency shifts to a low frequency at equal intervals as the electrode plates come closer to each other by 0.1 mm.

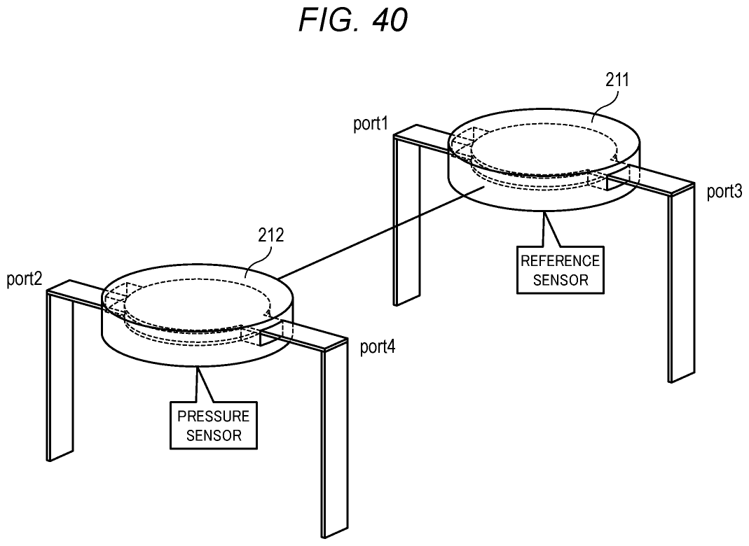

FIG. 40 is a diagram illustrating a simulation model of the sensor unit in the pressure detection device 210 according to the tenth embodiment, and in the simulation model thereof, sensors of the same shape are prepared, and one is used as the reference sensor 211 and the other is used as the pressure sensor 212. A difference in the passing characteristic illustrated in FIG. 39 is generated in such a manner that the space between the electrode plates changes by applying the pressure in the pressure sensor 212 to the reference sensor 211 and the capacitance changes according to the change in the space between the electrode plates. The pressure detection device 210 generates and detects the difference as the in-phase signal.

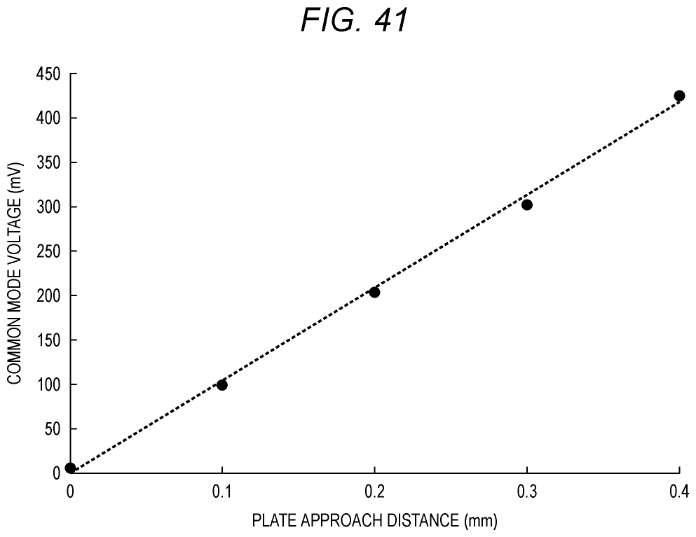

FIG. 41 is a diagram illustrating a simulation result using the models illustrated in FIGS. 38A to 38C and FIG. 40, and indicating a result of simulation performed by incorporating the S21 characteristics obtained by the electromagnetic field analysis illustrated in FIG. 39 into the sensor unit (reference sensor 211 and pressure sensor 212) illustrated in FIG. 37. In the simulation, a change in the common mode voltage with respect to the change in the space between the electrode plates of the sensors regarded as the pressure change is analyzed. The detection signal uses a differential sine wave of Vₚ₋ₚ100 mV at 100 MHz. The reason why the detection frequency is set to 100 MHz is that the difference in the frequency characteristics with respect to the change in the space between the electrode plates is clearly seen in the result of FIG. 39. As illustrated in FIG. 41, the common mode voltage when the space between the electrode plates is caused to closer by 0.1 mm linearly increases.

According to the pressure detection device 210 of the embodiment, the common mode detection method makes it possible to perform highly sensitivity sensing. Since the pressure is detected by comparison with the reference, it is possible not only to reduce the influence of an error factor such as an external environment, but also to perform highly accurate measurement. The sensitivity adjustment of the sensor can be performed without changing the shape of the sensor by adjusting the detection frequency. Thus, a change in pressure in a tire and a battery pack and a change in stress applied to a seat belt can be detected.

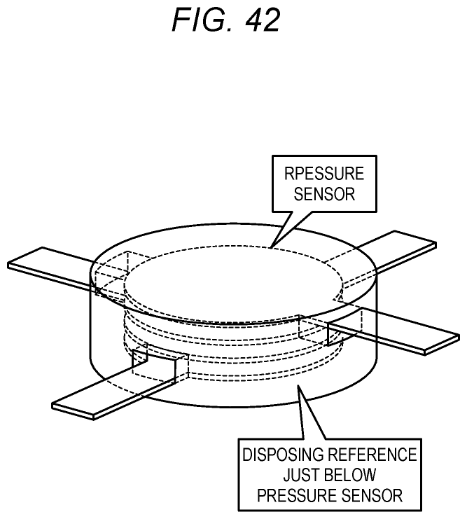

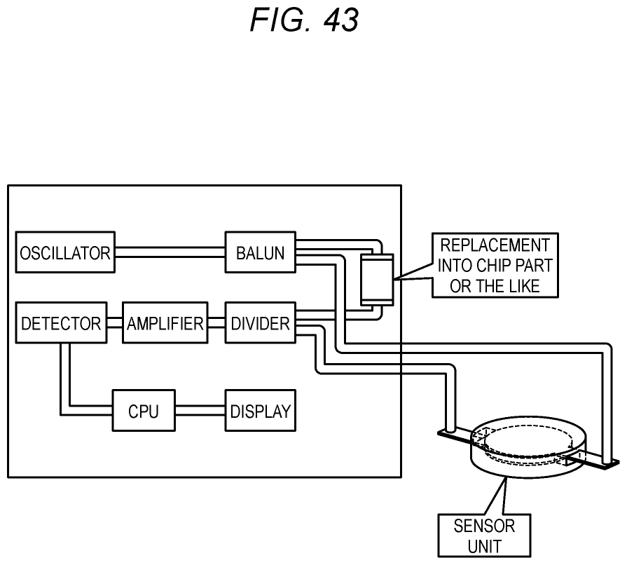

In the tenth embodiment, the sensor 213 is used for each of the reference sensor 211 and the pressure sensor 212 as the sensor unit, but both may be integrated. As illustrated in FIG. 42, the reference sensor is installed just below the pressure sensor and both are integrated, thereby making the sensor slim. As illustrated in FIG. 43, the reference sensor 211 can be replaced with a chip part such as a capacitor, thereby making the sensor slim.

### Eleventh Embodiment: Acceleration Detection Device

As an acceleration sensor that detects acceleration, for example, disclosed is an electrostatic capacitance type acceleration sensor that measures acceleration based upon a change in electrostatic capacitance between a movable electrode and a fixed electrode (refer to JP 2017-067500 A). In the acceleration sensor, a charge and voltage conversion circuit including a plurality of operational amplifiers, resistors, and capacitors converts a charge accumulated between the fixed electrode and the movable electrode into a voltage signal, and then outputs the converted voltage signal. The acceleration sensor performs a method in which a potential fluctuation difference between the fixed electrode and the movable electrode is captured, but has a configuration which easily causes an error of detecting a difference between the outputs of two operational amplifiers for detecting the capacitance with a next-stage operational amplifier. The aforementioned configuration has a drawback about real-time sensing and sensitivity. The acceleration sensor cannot adjust the sensitivity of the sensing after a detection system is manufactured. In the eleventh embodiment, an acceleration detection device capable of solving these problems will be described. The acceleration detection device according to the eleventh embodiment is an acceleration detection device to which the measurement system described in the first to fourth embodiments is applied.

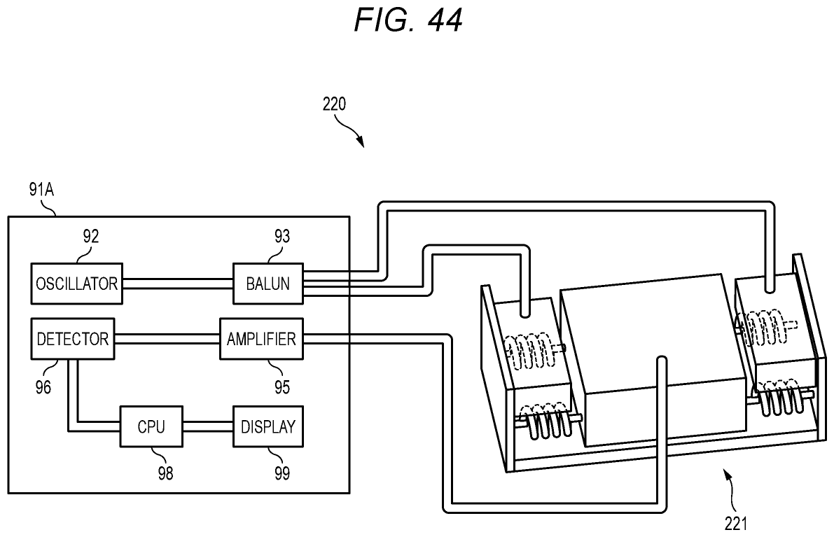

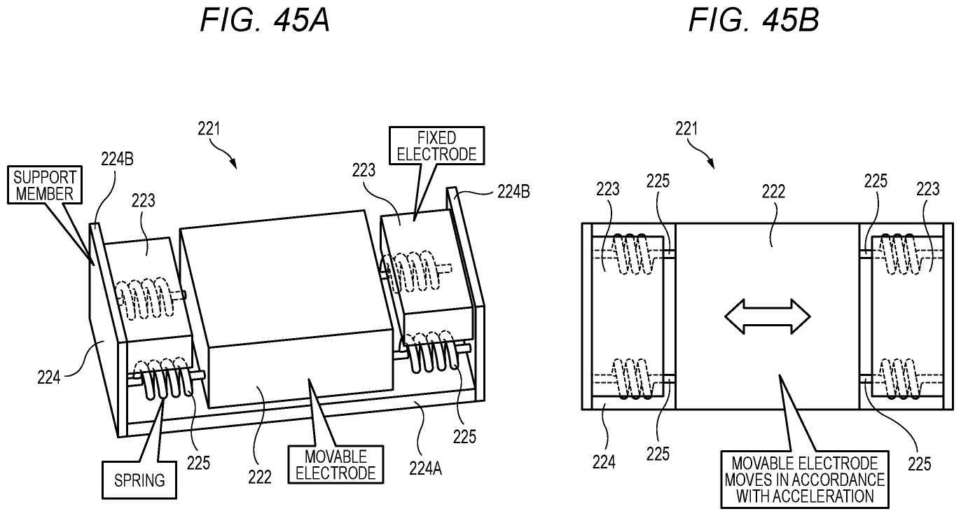

FIG. 44 is a diagram illustrating a configuration of an acceleration detection device 220 according to the eleventh embodiment. FIGS. 45A and 45B are diagrams illustrating a configuration of a sensor unit 221 in the acceleration detection device 220 according to the eleventh embodiment. The acceleration detection device 220 illustrated in FIG. 44 is formed by changing a part of the sensor unit and the determination unit 91 in the liquid level detection device 90 in FIG. 18. In the acceleration detection device 220 in FIG. 44 and the liquid level detection device 90 in FIG. 18, a configuration for executing the same function will be denoted by the same reference sign, and the redundant description thereof will be omitted. The acceleration detection device 220 illustrated in FIG. 44 is configured with the sensor unit 221 and a determination unit 91A. The determination unit 91A is formed by removing the divider 94 in the determination unit 91 illustrated in FIG. 18.

The sensor unit 221 is a uniaxial acceleration sensor and includes a movable electrode 222, a pair of fixed electrodes 223, a support member 224, and four springs 225 as illustrated in FIGS. 45A and 45B. The movable electrode 222 has a box shape and is disposed at the center of the support member 224. Each of the pair of fixed electrodes 223 has a box shape and is disposed at opposite ends of the movable electrode 222 at a predetermined space distance with the movable electrode 222. The support member 224 has a bottom plate 224A and a pair of side plates 224B provided upright at opposite ends of the bottom plate 224A, and has a U-shape in cross-sectional view along a vertical plane. Each fixed electrode 223 is fixed to each side plate 224B, and two springs 225 having one end fixed to the side plate 224B and the other end connected to the movable electrode 222 are elastically provided below the fixed electrode 223. That is, the movable electrode 222 is supported by the spring 225 fixed to the support member 224. When the movable electrode 222 moves with acceleration, a change in electrostatic capacitance between the electrodes (between the fixed electrode 223 and the movable electrode 222) at this time is converted into a moving amount, and the acceleration is calculated by a spring constant and mass of the movable electrode.

In the acceleration detection device 220 illustrated in FIG. 44, the balun 93 generates differential signals (positive signal and negative signal) from the signal for diagnosis generated by the oscillator 92, and the differential signals are respectively inputted to the pair of fixed electrodes 223. Thereafter, the signals that have passed according to the capacitance between the electrodes are combined through the movable electrode 222, that is, a signal difference according to a change in vibration of the movable electrode 222 is generated as the in-phase signal, and then inputted to the amplifier 95. The amplifier 95 amplifies the in-phase signal, that is, amplifies a signal of a difference generated from the amplitude and phase difference of both signals that have passed according to the capacitance between the electrodes. The detector 96 measures the in-phase signal amplified by the amplifier 95 and outputs the measured in-phase signal as a signal for analysis. The CPU 98 calculates acceleration from the measurement result of the in-phase signal. The display 99 displays the calculated acceleration.

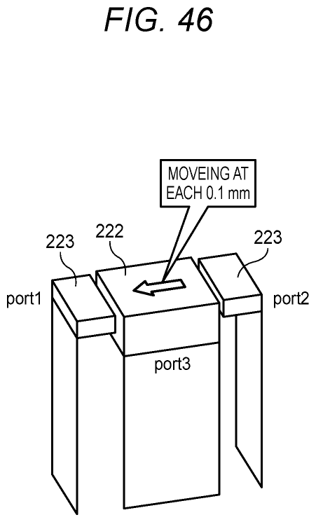

FIG. 46 is a diagram illustrating a simulation model of the sensor unit 221 illustrated in FIGS. 45A and 45B. In the model, the pair of fixed electrodes 223 are installed at a space of 1 mm with respect to the movable electrode 222 at the center. The differential signals from the balun 93 illustrated in FIG. 44 are respectively inputted to ports 1 and 2, and the signal from the movable electrode 222 after passing is outputted from a port 3. That is, the positive signal and the negative signal outputted from the balun 93 are respectively inputted from the port 1 and the port 2 to the pair of fixed electrodes 223. Next, the in-phase signal (common mode signal) generated by combining both the positive signal and the negative signal passing through between the electrodes as they are (non-inversion) is outputted from the port 3. In the model, the frequency characteristics in a state where the movable electrode 222 moves to the side of the port 1 by 0.1 mm according to the acceleration are analyzed.

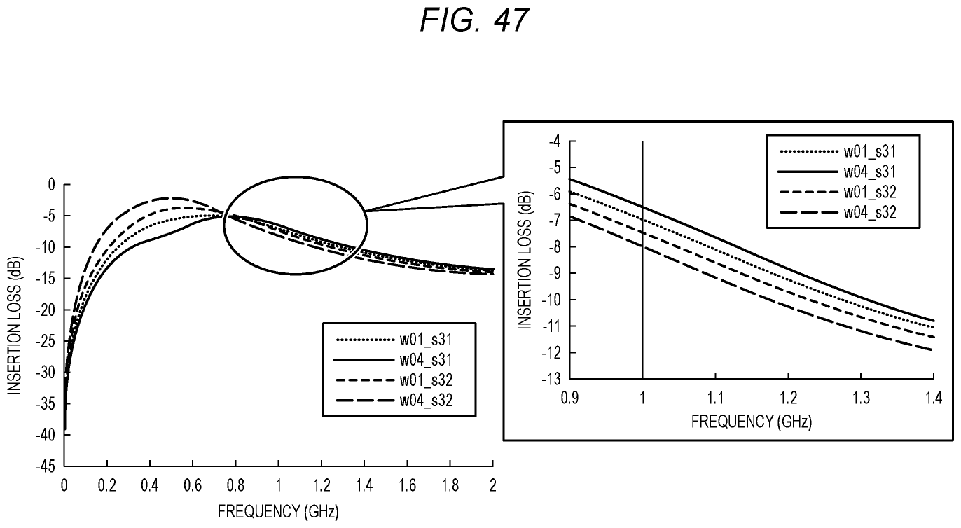

FIG. 47 is a diagram illustrating a simulation result (frequency characteristic change) using the model illustrated in FIG. 46. FIG. 47 picks up and illustrates characteristics when the movable electrode 222 moves to the side of the port 1 by 0.1 mm and 0.4 mm. As a tendency, since the capacitance increases as the movable electrode 222 (electrode plate) moves closer to one fixed electrode 223 by the movement of the movable electrode 222, a cut-off frequency of a passing signal moves to the low frequency side. At this time, since a space between the fixed electrode 223 on the reverse side and the movable electrode 222 is enlarged, the cut-off frequency of the passing signal moves to the high frequency side. Therefore, it is assumed that the large combined signal appearing in the port 3 is outputted as a moving distance of the electrode plate is large. In FIG. 47, w represents the moving distance of the movable electrode 222 (electrode plate), and for example, w01 indicates that the electrode plate has moved by 0.1 mm. When looking at the enlarged band on the right side of FIG. 47, it can be seen that the frequency characteristics change at equal intervals. When looking at a difference between a S31 parameter (w01_s31) which is 0.1 mm movement and a S32 parameter (w04_s32) which is 0.4 mm movement, it can be seen that in the case of 0.4 mm, there is a difference of about three times that in the case of 0.1 mm.

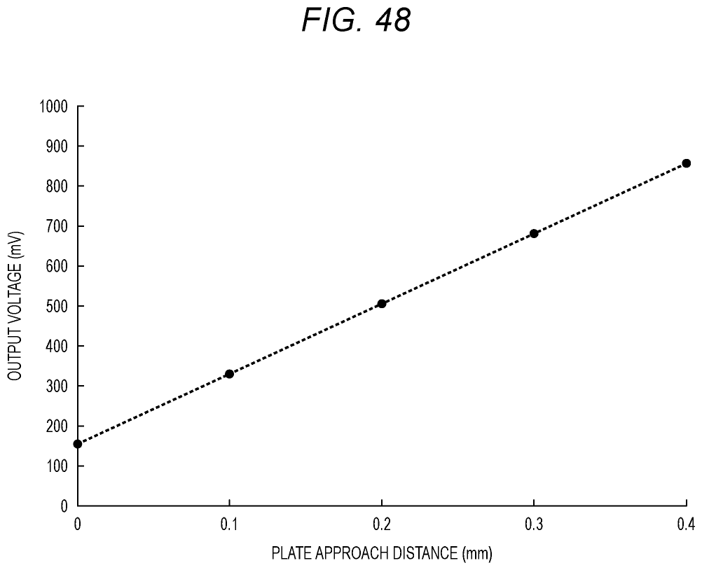

FIG. 48 is a diagram illustrating a simulation result (change in output voltage) using the model illustrated in FIG. 46. The detection signal uses a differential sine wave of Vₚ₋ₚ100 mV at 1 GHz. The reason why the detection frequency is set to 1 GHz is that the difference in frequency characteristics with respect to the change in the space between the electrode plates is clearly seen as a tendency in the result of FIG. 47.

According to the acceleration detection device 220 of the embodiment, a high frequency signal is extended to the electrode plate as it is, and the phase change difference as well as the amplitude change is taken at the same time and then outputted as the common mode voltage, such that it is possible not only to perform highly accurate measurement, but also to simplify the measurement system. As illustrated in the simulation result in FIG. 47, the acceleration detection device 220 indicates various sensitivities depending on the frequencies with respect to the movement of the movable electrode 222 (electrode plate), such that the measurement with high sensitivity frequency and multi-frequency can be performed by adjusting the detection frequency to be applied even though resonance by a bias voltage is not generated.

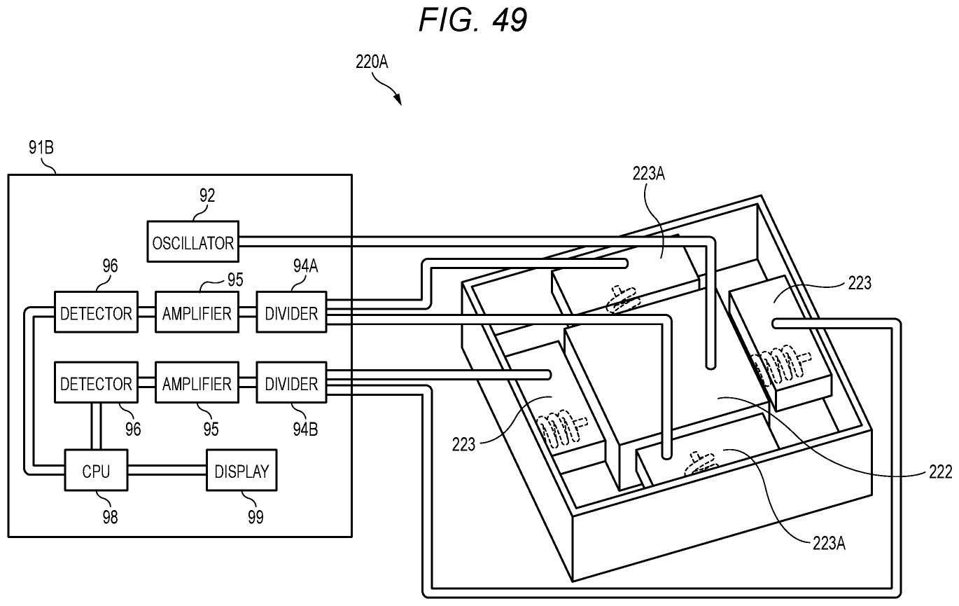

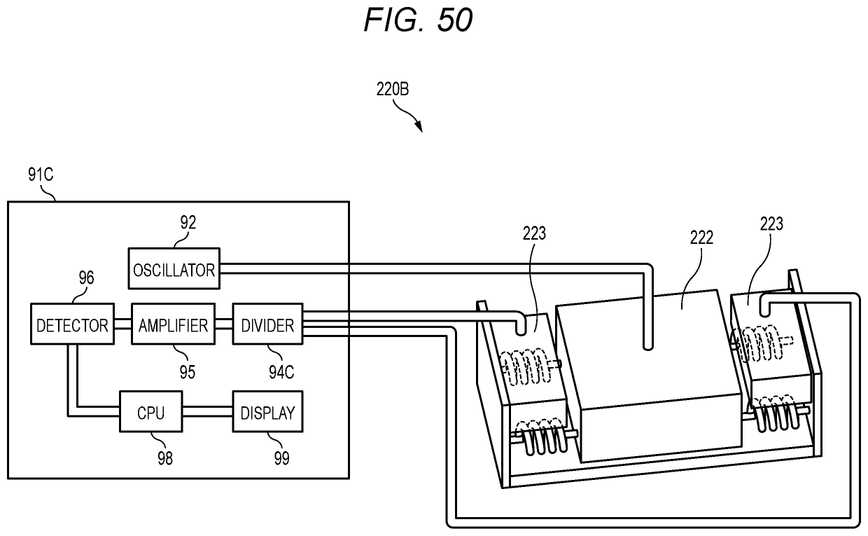

In the eleventh embodiment, the sensor unit 221 is an example of a uniaxial acceleration sensor, but as illustrated in FIG. 49, a pair of fixed electrodes 223A across the movable electrode 222 are provided in a direction orthogonal to the arrangement direction of the pair of fixed electrodes 223, thereby making it possible to form a biaxial acceleration sensor (acceleration detection device 220A). As illustrated in FIG. 50, it is also possible to from an acceleration detection device 220B having a method in which a signal is inputted to the movable electrode 222 and respective signals from the pair of fixed electrodes 223 are combined by the divider 94C to extract a difference between the two signals as the common mode signal. As illustrated in FIG. 49 and FIG. 50, the accuracy improvement of signal difference derivation can be expected by combining waveforms with dividers 94A to 94C in sensor units 91B and 91C.

### Twelfth Embodiment: Linear Sensor Device

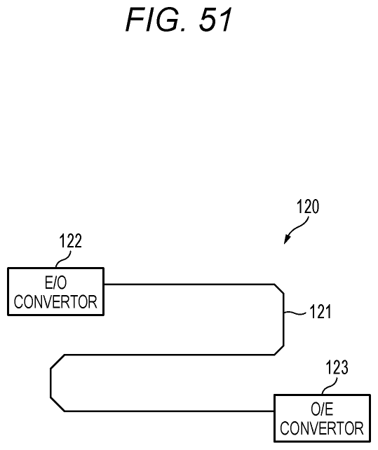

In a construction field and an aircraft material field, it is proposed to perform deterioration diagnosis by using an optical fiber sensor. As illustrated in FIG. 51, an optical fiber sensor 120 includes an E/O converter 122 that converts an electric signal into an optical signal and an O/E converter 123 that converts an optical signal into an electric signal at both ends of an optical fiber 121. The optical fiber sensor has a feature such as a small size, light weight, long life, and no need for power supply to the sensor unit. In particular, a distributed optical fiber sensor in which the optical fiber itself functions as a sensor can obtain a strain distribution positionally continuing along the entire length of the optical fiber. There are several types of scattered light generated in the optical fiber, and among them, Brillouin scattered light is a scattered phenomenon caused by an acoustic wave generated and propagated by incident light, and the incident light receives Doppler shift and a wavelength is shifted according to the frequency of the acoustic wave. The scattering occurs everywhere in the optical fiber and the wavelength of the scattered light depends on the strain of the generated position. Strain information can be obtained at all positions along the optical fiber. Many applications of a sensing technology using “natural Brillouin scattered light” by the incident light from one end of the optical fiber has been attempted in the construction field. On the other hand, a sensing technology using “stimulated Brillouin scattered light” by causing two lights to be opposite to each other at opposite ends of the optical fiber has been also actively developed, and a feature such as high spatial resolution is provided by the strong light intensity.

However, since the optical fiber sensor converts the electric signal into the optical signal (E/O conversion) and converts the optical signal into the electric signal again (O/E conversion), the signal loss is large. Therefore, energy conversion efficiency is low. A device for the O/E conversion is expensive and thus it is difficult to reduce the cost. On the other hand, the optical fiber sensor has a functional merit of a linear sensor capable of performing deterioration diagnosis with a line instead of a point. Therefore, a linear sensor technology that compensates for a drawback of the optical fiber sensor is required.

In the twelfth embodiment, the linear sensor that compensates for the drawback of the optical fiber sensor will be described. A linear sensor device according to the twelfth embodiment is a device to which the measurement system described in the first to fourth embodiments is applied. That is, in the measurement system 1 illustrated in FIG. 1, the transmission line (operation transmission line 10) between the communication devices A and B is used as the linear sensor, thereby making it possible to catch a place where an abnormality occurs with a point.

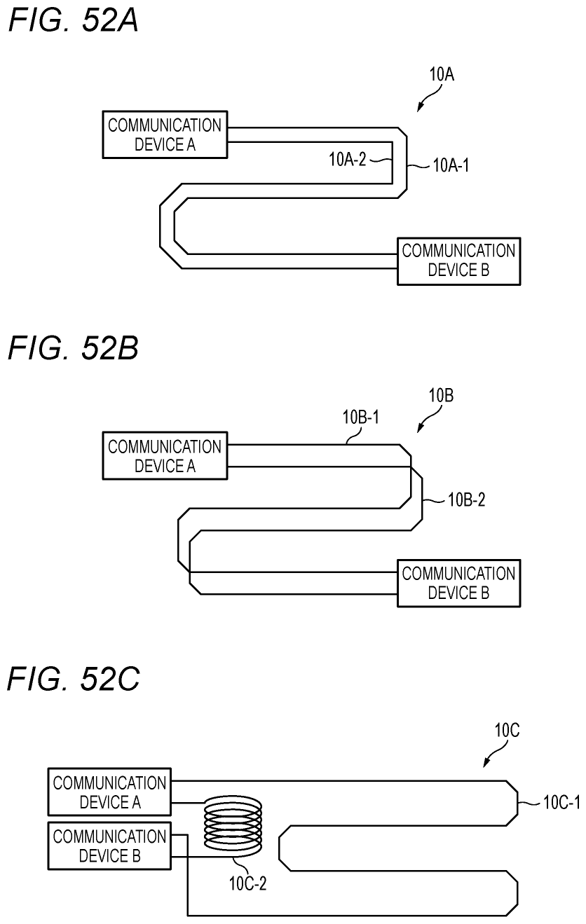

FIGS. 52A to 52C are diagrams illustrating examples of the arrangement of the linear sensor according to the twelfth embodiment, and illustrating examples of the arrangement as a two-dimensionally distributed linear sensor. A linear sensor 10A illustrated in FIG. 52A is formed by arranging two lines 10A-1 and 10A-2 having the same line length in parallel. This arrangement method is suitable for a case where a difference is predicted even though a distance between the two lines is narrow. A linear sensor 10B illustrated in FIG. 52B is formed in such a manner that two lines 10B-1 and 10B-2 having the same line length are arranged in parallel so as to complement each other. According to this arrangement method, the distance between the two lines can be widened and thus the difference can be easily caught. The two sensors can be used as sensors, which is different from a case of FIG. 52C. In a linear sensor 10C illustrated in FIG. 52C, one line 10C-1 of the two lines 10C-1 and 10C-2 having the same line length is used for measurement, and the other line 10C-2 is used for reference. According to this arrangement method, the difference between the two lines becomes maximum, thereby being suitable for precise measurement.

According to the embodiment, in the measurement system described in the first to fourth embodiments, the operation transmission line 10 is used as the linear sensors 10A to 10C, thereby making it possible to form the linear sensor device which can be configured only by the electrical signal without using the optical fiber. According to the linear sensor, even though the loss of the transmission line itself is larger than that of the optical fiber, energy utilization efficiency is high by reducing the loss at the time of performing the E/O and O/E conversion. Therefore, it is considered that the optical fiber is suitable for long-distance use and the linear sensor of the embodiment is suitable for short-distance use. The cost comparison is also assumed to be the same.

Here, the characteristics of the measurement method, the transmission line diagnostic device, the detection device, and the linear sensor device according to the embodiments of the present invention described above are briefly described below.

According to an aspect of the present disclosure, a measurement method includes generating (combiner (5)) an in-phase signal by combining a first signal transmitted through a first transmission line and a second signal transmitted through a second transmission line in a pair of differential transmission lines (10) including the first transmission line through which the first signal is transmitted and the second transmission line through which the second signal whose phase is opposite to the first signal is transmitted, and measuring (measuring device (C)) the generated in-phase signal.

According to the aspect of the present disclosure, the measuring method further includes amplifying (low noise amplifier (17)) the generated in-phase signal, and measuring the amplified in-phase signal.

According to the aspect of the present disclosure, the measuring method further includes measuring the generated in-phase signal after a signal of a frequency band higher than a target frequency band is attenuated (filter (16)).

According to the aspect of the present disclosure, the measuring method further includes extracting the first signal transmitted through the first transmission line and the second signal transmitted through the second transmission line by a directional coupler.

According to another aspect of the present disclosure, a diagnostic device for diagnosing a transmission line includes a mounting unit (connectors (53, 55)) on which a pair of differential transmission lines (cable (70)) including a first transmission line through which a first signal is transmitted and a second transmission line through which a second signal whose phase is opposite to the first signal is transmitted is mounted, a first communication unit (communication chip (52)) configured to transmit the first signal and the second signal to the differential transmission line via the mounting unit, a second communication unit (communication chip (56)) configured to receive the first signal and the second signal from the differential transmission line via the mounting unit, a signal combiner (divider (57)) configured to extract the first signal and the second signal received by the second communication unit, combine the extracted first and second signals, and generate an in-phase signal, a detector (detector (59)) configured to detect the generated in-phase signal.

According the aspect of the present disclosure, the diagnostic device further includes a determination unit (detector (59)) configured to determine an error when a magnitude of the detected in-phase signal is equal to or greater than a threshold value.

According the aspect of the present disclosure, the diagnostic device further includes an amplifier (58) configured to amplify the in-phase signal generated by the signal combiner, in which the detector detects the in-phase signal amplified by the amplifier.

According to the aspect of the present disclosure, the determination unit determines whether the error exists by extracting the first signal and the second signal received by the second communication unit and comparing the extracted first and second signals with data of a normal characteristic stored in a memory.

According to another aspect of the present disclosure, a detection device (liquid level detection device 90) includes a first line (pattern (PA1)) to which a first signal is inputted, a second line (pattern (PA2)) to which a second signal whose phase is opposite to the first signal is inputted, a combining unit (divider (94)) configured to combine the first signal transmitted through the first line and the second signal transmitted through the second line and generate an in-phase signal, a detection unit (detector (96)) configured to detect a voltage of the generated in-phase signal, and a calculation unit (CPU (98)) configured to calculate a liquid level from the detected voltage.

According to the aspect of the present disclosure, the detection device further includes an amplification unit (amplifier (95)) configured to amplify the generated in-phase signal, in which the detection unit detects a voltage of the amplified in-phase signal.

According to the aspect of the present disclosure, the calculation unit calculates the liquid level with reference to a table indicating the correspondence between the liquid level and the voltage.

According to the aspect of the present disclosure, the first line includes a first open stub (ST1). The second line includes a second open stub (ST2). The combining unit generates the in-phase signal by combining the first signal passing through the first open stub and the second signal passing through the second open stub.

According to another aspect of the present disclosure, a detection device (displacement detection device (200), pressure detection device (210)) includes a first sensor (reference sensor (201, 211)) to which a first signal is inputted, a second sensor (displacement sensor (202), pressure sensor (212)) to which a second signal whose phase is opposite to the first signal is inputted, a combining unit (divider (94)) configured to combine the first signal passing through the first sensor and the second signal passing through the second sensor and generate an in-phase signal, a detection unit (detector (96)) configured to detect a voltage of the generated in-phase signal, and a calculation unit (CPU (98)) configured to calculate a displacement level or pressure from the detected voltage.

According to the aspect of the present disclosure, at least one of the first sensor and the second sensor includes a loop coil (203). The calculation unit calculates a distance between the loop coil and a measured object, the distance corresponding to the displacement level.

According to the aspect of the present disclosure, each of the first sensor and the second sensor includes a pair of electrode plates disposed to be spaced apart from each other, and the calculation unit calculates a distance between the pair of electrode plates to be changed by pressurization, the distance corresponding to the pressure.

According to another aspect of the present disclosure, a detection device (acceleration sensor device (220)) includes a movable electrode (222), first and second fixed electrodes (223) that are disposed to be spaced apart from the movable electrode and are opposite to each other across the movable electrode, a detection unit (detector (96)) configured to detect a voltage of an in-phase signal obtained by combining a first signal passing through between the movable electrode and the first fixed electrode and a second signal passing through between the movable electrode and the second fixed electrode, and a calculation unit (CPU (98)) configured to calculate acceleration from the detected voltage.

According to another aspect of the present disclosure, a linear sensor device includes two communication devices (A, B), first and second transmission lines (10A, 10B, 10C) having the same line length that are disposed between the two communication devices, a combiner (5) configured to combine a first signal passing through the first transmission line and a second signal passing through the second transmission line and generate an in-phase signal; and a measurement device (C) that measures the generated in-phase signal.

According to the measurement method, since the in-phase signal obtained by combining the first signal and the second signal without inverting the first signal and the second signal can capture a shift in an amplitude and a phase between the pair of transmission lines more than a differential signal obtained by combining the first signal and the inverted second signal, a change in the transmission line can be easily detected, and the measurement system can be simplified.

According to the measurement method, a minute change in the transmission line can be easily detected by amplifying the in-phase signal.

According to the measurement method, since noise overlapped on an unnecessary band can be removed, a stable detection output can be obtained with higher sensitivity.

According to the measurement method, when an original signal flowing through the differential transmission line is separated and extracted, the loss of the original signal can be minimized. Since it is possible to distinguish where an abnormality occurs in the front and rear places centering on an arrangement place (a signal separation position) of a directional coupler, a function as a sensor of a differential transmission system can be improved.

According to the diagnostic device for diagnosing the transmission line, since the in-phase signal obtained by combining the first signal and the second signal without inverting the first signal and the second signal can capture the shift in the amplitude and the phase between the pair of transmission lines more than the differential signal obtained by combining the first signal and the inverted second signal, the change in the transmission line can be easily detected such that a minute error can be detected. Since the transmission line diagnostic device is not limited to a method of using a diagnostic signal as the first signal and the second signal and can perform diagnosis using an actual communication signal, the transmission line diagnostic device is highly versatile. When performing the diagnosis using the communication signal, since a communication system using a differential transmission line (a cable, and the like) which is an object to be diagnosed can be used as it is, it is not required to separately construct a diagnostic system for inputting and outputting the diagnostic signal, thereby making it possible to simplify the diagnostic system.

According to the diagnostic device, a minute change in the transmission line can be easily detected by amplifying the in-phase signal.

According to the diagnostic device, even if an error of the same degree is generated in the first transmission line and the second transmission line and a phase difference is not generated between the first signal and the second signal, when a difference exists between data of the first and second signals and data of a normal characteristic, the error of the same degree can be detected as an error, whereby it is possible to perform highly accurate diagnosis.

According to the detection device, a difference corresponding to the liquid level appears as a level of the in-phase signal by installing the first line in a tank which is a measured object for liquid level detection and by using the second line as a reference for correction. That is, since a phase change can be detected instead of an amplitude change of the first signal and the second signal, the liquid level can be detected with high accuracy. Since a sensor is not a capacitance detection type sensor in a related art, a straight-line pattern is sufficient, and since a comb-teeth type pattern for providing capacitance to a substrate of a sensor unit is not required, a sensor shape can be slimmed.

According to the detection device, a minute change in the liquid level can be easily detected by amplifying the in-phase signal.

According to the detection device, the liquid level can be easily calculated with reference to the table prepared in advance.

According to the detection device, the liquid level can be detected only by the open stub and thus the element can be slimmed.

According to the detection device, the displacement, pressure and acceleration can be detected with high accuracy by using the in-phase signal combined without inverting the first signal and the second signal.

According to the linear sensor device, the linear sensor that compensates for a drawback of the optical fiber sensor (conversion loss is large and energy efficiency is low) can be realized.

### REFERENCE SIGNS LIST

1 measurement system
5 combiner
10 differential transmission line
10A to 10C linear sensor
11 measurement system
12 communication substrate
13 communication substrate
13a communication chip
15 power adder
16 filter
17 low noise amplifier
18 wave detector
19 monitoring device
20 differential cable
21 measurement system
50 cable diagnostic device
51 substrate
52 communication chip
53 connector
54 substrate
55 connector
56 communication chip
57 divider
58 amplifier
59 detector
60 LED
70 cable
71 substrate
80 cable diagnostic device
81 common mode detection unit
82 amplitude change detection unit
83 memory
84 determination unit CPU
85 LED
90 liquid level detection device
91 determination unit
92 oscillator
93 balun
94 divider
95 amplifier
96 detector
97 common mode detection unit
98 CPU
99 display
100 measurement system
101 combiner
110 differential transmission cable
110 signal line (differential transmission cable)
200 displacement detection device
201, 211 reference sensor
202 displacement sensor
212 pressure sensor
220 acceleration detection device
222 movable electrode
223, 223A fixed electrode
A communication device
B communication device
C measurement device
CB combiner
D driver
R receiver
ST1, ST2 open stub
SU1, SU1A liquid level detection substrate
SU2, SU2A reference substrate
T tank

What is claimed is:

1. A measurement method, comprising:
generating an in-phase signal by combining a first signal transmitted through a first transmission line and a second signal transmitted through a second transmission line in a pair of differential transmission lines including the first transmission line through which the first signal is transmitted and the second transmission line through which the second signal whose phase is opposite to the first signal is transmitted; and
measuring the generated in-phase signal.

2. The measurement method according to claim 1, further comprising:
amplifying the generated in-phase signal, and
measuring the amplified in-phase signal.

3. The measurement method according to claim 1, further comprising:
measuring the generated in-phase signal after a signal of a frequency band higher than a target frequency band is attenuated.

4. The measurement method according to claim 1, further comprising:
extracting the first signal transmitted through the first transmission line and the second signal transmitted through the second transmission line by a directional coupler.

5. A diagnostic device for diagnosing a transmission line, comprising:
a mounting unit on which a pair of differential transmission lines including a first transmission line through which a first signal is transmitted and a second transmission line through which a second signal whose phase is opposite to the first signal is transmitted is mounted;
a first communication unit configured to transmit the first signal and the second signal to the differential transmission line via the mounting unit;
a second communication unit configured to receive the first signal and the second signal from the differential transmission line via the mounting unit;
a signal combiner configured to extract the first signal and the second signal received by the second communication unit, combine the extracted first and second signals, and generate an in-phase signal;
a detector configured to detect the generated in-phase signal.

6. The diagnostic device according to claim 5, wherein the diagnostic device further comprises a determination unit configured to determine an error when a magnitude of the detected in-phase signal is equal to or greater than a threshold value.

7. The diagnostic device according to claim 5, further comprising:
an amplifier configured to amplify the in-phase signal generated by the signal combiner,
wherein the detector detects the in-phase signal amplified by the amplifier.

8. The diagnostic device according to claim 5,
wherein the determination unit determines whether the error exists by extracting the first signal and the second signal received by the second communication unit and comparing the extracted first and second signals with data of a normal characteristic stored in a memory.

9. A detection device, comprising:
a first line to which a first signal is inputted;
a second line to which a second signal whose phase is opposite to the first signal is inputted;
a combining unit configured to combine the first signal transmitted through the first line and the second signal transmitted through the second line and generate an in-phase signal;
a detection unit configured to detect a voltage of the generated in-phase signal; and
a calculation unit configured to calculate a liquid level from the detected voltage.

10. The detection device according to claim 9, further comprising:
an amplification unit configured to amplify the generated in-phase signal,
wherein the detection unit detects a voltage of the amplified in-phase signal.

11. The detection device according to claim 9,
wherein the calculation unit calculates the liquid level with reference to a table indicating the correspondence between the liquid level and the voltage.

12. The detection device according to claim 9,
wherein the first line includes a first open stub,
wherein the second line includes a second open stub, and
wherein the combining unit generates the in-phase signal by combining the first signal passing through the first open stub and the second signal passing through the second open stub.

13. A detection device, comprising:
a first sensor to which a first signal is inputted;
a second sensor to which a second signal whose phase is opposite to the first signal is inputted;
a combining unit configured to generate an in-phase signal by combining the first signal passing through the first sensor and the second signal passing through the second sensor;
a detection unit configured to detect a voltage of the generated in-phase signal; and
a calculation unit configured to calculate a displacement level or a pressure from the detected voltage.

14. The detection device according to claim 13,
wherein at least one of the first sensor and the second sensor includes a loop coil, and
wherein the calculation unit is configured to calculate a distance between the loop coil and a measured object, the distance corresponding to the displacement level.

15. The detection device according to claim 13,
wherein each of the first sensor and the second sensor includes a pair of electrode plates which is disposed to be spaced apart from each other, and
wherein the calculation unit is configured to calculate a distance between the pair of electrode plates to be changed by pressurization, the distance corresponding to the pressure.

16. A detection device, comprising:
a movable electrode;
a first fixed electrode and a second fixed electrode that are disposed to be spaced apart from the movable electrode and are opposite to each other across the movable electrode;
a detection unit configured to detect a voltage of an in-phase signal obtained by combining a first signal passing through between the movable electrode and the first fixed electrode, and a second signal passing through between the movable electrode and the second fixed electrode; and
a calculation unit configured to calculate an acceleration from the detected voltage.

17. A linear sensor device, comprising:
at least two communication devices;
a first transmission line and a second transmission line that are disposed between the at least two communication devices, the first transmission line and the second transmission line having a line length substantially same as each other;
a combiner configured to generate an in-phase signal by combining a first signal passing through the first transmission line and a second signal passing through the second transmission line; and
a measurement device that is configured to measure the generated in-phase signal.
